(19) United States
(12) Patent Application Publication
(10) Pub. No.: US 2025/0063846 A1
(43) Pub. Date: Feb. 20, 2025

(54) ADJACENT COMPENSATED CODOPING IN SEMICONDUCTOR MATERIALS

(71) Applicant: CENTRO DE INVESTIGACIÓN Y DE ESTUDIOS AVANZADOS DEL INSTITUTO POLITECNICO NACIONAL, Zapopan (MX)

(72) Inventors: Sergio Joaquin JIMENEZ SANDOVAL, Santiago de Queretaro (MX); Abraham Israel CALDERON MARTINEZ, Santiago de Queretaro (MX); Omar JIMENEZ SANDOVAL, Santiago de Queretaro (MX)

(73) Assignee: CENTRO DE INVESTIGACIÓN Y DE ESTUDIOS AVANZADOS DEL INSTITUTO POLITECNICO NACIONAL, Zapopan (MX)

(21) Appl. No.: 18/588,027

(22) Filed: Feb. 27, 2024

(30) Foreign Application Priority Data
Aug. 15, 2023 (MX) MX/A/2023/009534

(51) Int. Cl. H01L 31/18; H01L 31/0288; H01L 31/0296

(52) U.S. Cl. CPC H01L 31/1828; H01L 31/0288; H01L 31/02963; H01L 31/1808

(57) ABSTRACT

A process for impurification of semiconductor materials, comprising adjacent compensated codoping comprising: (a) providing a multicomponent host material AEGJ . . . ; (b) selecting two impurities Q and X codopants elements under the following scheme: (i) considering the host A and G, impurity Q is the chemical element with atomic number Z_{A}−1 and impurity X is the chemical element with atomic number Z_{G}+1; or impurity Q is the chemical element with atomic number Z_{A}+1 and impurity X is the chemical element with atomic number Z_{G}−1; or (ii) considering the host A and G, impurity Q is the chemical element with atomic number Z_{A}−2 and impurity X is the chemical element with atomic number Z_{G}+2; or impurity Q is the chemical element with atomic number Z_{A}+2 and impurity X is the chemical element with atomic number Z_{G}−2; or (iii) considering the host A and G, impurity Q is the chemical element with atomic number Z_{A}−1 and impurity X is the chemical element with atomic number Z_{G}+2; or impurity Q is the chemical element with atomic number Z_{A}+2 and impurity X is the chemical element with atomic number Z_{G}−1; and (c) performing the host adjacent codoping process with the selected impurities.

### FIELD OF THE INVENTION

The present invention relates to codoped semiconductor materials that improves the electrical conductivity, photocurrent and other electronic properties, and methods for obtaining these.

### BACKGROUND OF THE INVENTION

The present invention relates to a specific codoping method comprising the selection of impurities to be incorporated into a host material that modifies fundamentally its electrical and photoelectronic properties. The invention describes a way of choosing two impurities (herein called adjacent codopants) named in this way by their position in the Periodic Table with respect to the chemical elements forming the host material.

At present, electronic and optoelectronic technology is mainly based on semiconductor materials. The practical use of these materials requires the incorporation of impurities (dopants) in such a way that their electrical and optical properties are modified.

Depending on the impurities used, a semiconductor can be n-type, doped with donor impurities, or p-type, doped with acceptor impurities. The union of materials with these characteristics gives rise to a wealth of physical properties, which are central to the design and operation of various devices such as transistors, sensors, solar cells, light-emitting diodes, lasers and photodetectors, to mention some of the most relevant. Success in semiconductor impurification has gone hand in hand with the development of optoelectronic devices. At the same time, failures in doing so have limited the ability to improve existing technologies or develop new devices.

Among the most common problems related to doping semiconductors are the following:

(i) Low solubility of impurities in the host. That is, above a certain concentration of dopants, they are no longer homogeneously distributed in the host but tend to form aggregates and/or react chemically with the host, forming undesirable secondary compounds.

(ii) Formation of deep electronic levels of impurities within the forbidden band. The impurity-induced defect levels are located far away from the conduction and/or valence band edges (large activation energies) of the semiconductor, so that they are not useful for generating free charge carriers that would improve the electrical conduction.

(iii) After a certain threshold concentration, the host material may react to the presence of impurities, forming defects with a charge opposite to the type generated by the impurities (called self-compensating defects or complexes), such that further incorporation of dopants does not result in an increase in the conductivity of the material (e.g., DX centers [1, 2], or AX centers [3, 4]).

(iv) Ambipolar impurification (n-type and p-type) is not possible. Most semiconductors have some facility to be either n-type or p-type, but not both. That is, it can be extremely difficult to achieve one type of impurification and only in a few cases have both types been successfully achieved.

These difficulties for semiconductor doping have been discussed in detail for the case of simple impurification (incorporation of a single type of impurity or dopant) and there are excellent review articles on this subject [5-8]. Examples of cases where doping problems have been solved include p-type doping in II-VI semiconductors for lasers emitting in the blue [9, 10], p-type doping of nitrides [11, 12], p-type doping in oxides for displays and transparent electronics [13], improvements in doping active layers in solar cells [14], and efficient doping of nanocrystals [15, 16], and two-dimensional and quantum materials [18].

Codoping (or dual doping) has been one of the avenues pursued to modify the electronic properties of semiconductors in order to solve all or some of the problems (i)-(iv) above. In some cases, dual impurification has proven to be effective in improving solubility and deep electronic level formation problems. It is worth mentioning that to date reports on codoping, unlike the adjacent compensated codoping described here, have not been performed using any specific methodology to select the pair of chemical elements (impurities), other than their expected n- or p-type characteristic (that is, the relation between the valence of the impurities and those of the atoms in the host).

A chronological description of the codoping performed to date can be found in reference [18]. In some cases where codoping has been applied it has been through the so-called partially compensated codoping, in which different amounts of donor and acceptor impurities are introduced into the host material; for example, codoping with a single donor and a double acceptor. In this line of work, it is worth mentioning the partial compensation codoping method work of H. Katayama Yoshida's group, who employed codoping methods and theoretical calculations in large bandgap semiconductors to prepare p-type GaN and AlN, n-type diamond and p-type ZnO [20]. In the partially compensated codoping method used by Katayama et al., acceptor-donor-acceptor (A-D-A) and donor-acceptor-donor (D-A-D) combinations of impurities were incorporated into various host materials to produce p-type or n-type semiconductors, respectively. Examples of this codoping method include p-GaN:(Si+2 Mg), p-AlN:(O+2C), n-diamond C:(B+2N) and p-ZnO:(Al+2N) [19]. In these cases, the solubility of the impurities increased while the activation energy decreased.

Another approach in dual doping has been the so-called fully compensated codoping in which the incorporation of n-type and p-type impurities (or defects) are compensated totally to induce electrical neutrality. Its use, however, does not improve the electrical properties, but can produce strong effects on the electronic band structure [18], when seeking to improve the performance, for example, of photocatalytic materials for hydrogen production as in the case of TiO₂ [21].

Another example on the effect of codoping on the electronic band structure concerns zinc oxide codoped with copper and tellurium ZnO:(Cu+Te) in which the forbidden band of ZnO varied from 3.2 to 1.8 eV, depending on the concentration of Cu and Te. From a theoretical point of view, codoping effects were recently investigated in CdTe using first-principles methods with hybrid functionals [23]. The study was based on predicting the obtention of p-type material given its relevance for solar cell technology. Several complexes of the type:single donor+double acceptor (Cl_{Te}+V_{Cd}), two acceptors+one donor (2Cu_{Cd}+Cl_{Te}) and a deep acceptor+a shallow, or non-deep, acceptor (Sb_{Te}+P_{Te}) were analyzed.

It is emphasized that previous work has no bearing on the type of codoping proposed here. Previous approaches to codoping have focused on the valence states of acceptors and donors and the consequent charge balance/unbalance of free carriers (uncompensated, partially or fully compensated codoping), on the possible formation of natural charge-compensating defects by the host material, and on impurities solubility issues. To date, no methodology has been established to select codopants by their position in the Periodic Table with respect to chemical elements forming the material to be impurified (host) as stablished here. In the adjacent compensated codoping proposed here, a new methodology for selecting the codopant elements (impurities) is specified as well as the expected beneficial effects under the adjacent compensated codoping scheme over the physical properties of the codoped material such as reduction of the stresses introduced into the crystalline lattice, low perturbation of the vibrational dynamics of the crystalline lattice of the host, minimal electronegativity differences between codopants and host atoms which avoids abrupt chemical bonds changes, reduction in the formation of charge compensating defects (defects/complexes), and the generation of shallow levels within the forbidden bandgap by the selected codopants is favored. These effects are discussed further below.

With respect to the prior art close to the invention in patent documents, the following are notorious:

Patent Application KR 20080084464 Methods for making semiconductor devices. It relates to a method that increases the doping density with an n-type material and with another p-type material, the method involves forming a layer with n-type silicon oxide and then a layer with p-type silicon oxide on a semiconductor substrate.

European Patent EP 0903429B1 Process for producing highly doped silicon. It refers to a method for obtaining n-type or p-type silicon and is produced by doping it with at least one element X which may be P, As, or Sb whose ionic radius is greater than that of Si, together with at least another element Y selected from B, Al, Ga or In whose ionic radius is less than that of Si, wherein the Si crystal is grown in high concentrations of the dopants to become highly doped; the double doping of Si with n-type and p-type dopants is considered. However, this method is limited to silicon materials and is based on a different criteria than that of the present invention.

### SUMMARY OF THE INVENTION

It is the principal object of the invention to generate semiconductor materials with modified electronic properties to improve the electrical and/or photoelectronic properties.

It is an object of the invention to generate codoped semiconductor materials in such a way as to present a reduced electrical resistivity, without affecting importantly either their optical properties or their crystalline lattice vibrational dynamics (phononic properties).

Another object of the invention consists in providing codoped materials exhibiting ambipolar impurification (n-type and p-type).

Another object of the invention consists in providing a codoped material with a homogeneous distribution of impurities in the matrix.

Still another object of the invention consists in reducing and/or preventing the formation of unwanted secondary phases or compounds.

Another object of the invention consists in generating semiconductor materials whose transfer of electrons to the conduction band and of holes to the valence band is favored.

Another object of the invention involves using adjacent codopant elements to generate shallow levels in the forbidden band of the host due to the expected proximity (shallow) of the electronic levels of the impurities to the edges of the conduction and valence bands.

Another object of the invention relates to realizing codoping by simultaneous incorporation of n-type (donor) and p-type (acceptor) impurities nominally in a one-to-one ratio (or close to it), which allows increasing the free carrier density before defect generation.

Still another object of the invention consists in preventing the reaction of the host material caused by impurities, and thereby self-compensating defects and/or complexes.

The above objects are achieved by means of a method of codoping the host material, and depends on a crucial step consisting in the way the two codopants are selected, which must be adjacent elements according to the Periodic Table of the chemical elements, also called impurities 1 and 2. The selection criterion is as follows: select the element that is impurity 1 whose atomic number is greater by one (or two units) than that of one of the chemical elements forming the host material, and select the element that is impurity 2, whose atomic number is lower by one (or two) unit(s) with respect to other of the chemical elements forming the host material.

### BRIEF DESCRIPTION OF THE DRAWINGS

By way of example, reference is now made to the accompanying drawings.

FIG. 1 is a schematic representation of the adjacent compensated codoping (ACC) method illustrating the characteristics of adjacent codopants (upper text), and their effects on the host material (lower text), after the arrow.

FIG. 2 shows a portion of the periodic table of the chemical elements where the concept of adjacent codopants is illustrated for the case of cadmium telluride (CdTe).

FIG. 3 shows the chemical composition of the CdTe films, obtained by energy dispersive spectroscopy (EDS), deposited by the radiofrequency sputtering technique, as a function of the concentration (atomic percentage) of silver iodide (AgI) in the target from which the films were deposited.

FIG. 4A and FIG. 4B, respectively, show the X-ray diffraction patterns of CdTe and CdTe:(Ag+I) films for the concentrations of (AgI) in the target from 0.5 at. % to 7 at. %, as indicated.

FIG. 5 shows the X-ray diffraction patterns of CdTe films grown at 275° C. using targets with 0.5 and 3.0 at. % of silver.

FIG. 6 is a plot of the values of the lattice parameter in CdTe:(Ag+I) films as a function of the concentration of AgI in the target.

FIG. 7A and FIG. 7B show, respectively, the optical transmission of (a) CdTe and of (b) CdTe:(Ag+I) films in the range from 400 to 1500 nm for different concentrations of (AgI) in the target. For clarity, in (b) the spectra were vertically shifted as specified on the right-hand side of each spectrum.

FIG. 8A and FIG. 8B show the Raman spectra measured at room temperature of the CdTe and CdTe:(Ag+I) films for the (AgI) concentrations in the sputtering target from 0.5 at. % to 3 at. %, and from 4 at. % to 7 at. %, respectively.

FIG. 9 shows the values of the free charge carrier concentration, mobility and resistivity of the CdTe:(Ag+I) films for adjacent codopant concentrations (Ag+I) between 4 and 7 at. %. The measurements were performed at room temperature in an Ecopia Hall Effect system model HMS5000.

FIG. 10 shows an experimental setup of the white light photoconductivity measurements under constant illumination. 101: Xenon lamp; 102: electrical contacts; 103: film (sample) to be measured; 104: glass substrate.

FIG. 11 shows the current-voltage response of the CdTe film in the dark and under illumination.

FIG. 12A shows current-voltage (photocurrent) plot of the CdTe:(Ag+I) film with 5 at. % of codopants under illumination and in the dark.

FIG. 12B shows the values of photosensitivity (r=I_{Light}/I_{Dark}) of the CdTe:(Ag+I) films as a function of the concentration of adjacent codopants (Ag+I).

FIG. 13. Portion of the periodic table of the chemical elements where the concept of adjacent codopants is illustrated for the case of the compound cadmium sulfide (CdS). In this case, silver is selected because it is the element with atomic number one unit lower than cadmium and chlorine because it is the element with atomic number one unit higher than sulfur. To achieve the incorporation of these elements, the compound silver chloride (AgCl) was used in the fabrication of the targets used to deposit the CdS:(Ag+Cl) films.

FIG. 14A and FIG. 14B show, respectively, (a) the chemical composition of the CdS:(Ag+Cl) films as a function of AgCl concentration in the sputtering target; and (b) the X-ray diffraction patterns of the films for different concentrations of (Ag+Cl). For reference, the intensities of the reference diffraction pattern of the wurtzite-type hexagonal CdS powder (PDF #41-1049) are presented at the bottom.

FIG. 15A and FIG. 15B show, respectively, (a) the variation of the lattice parameter c, and (b) of the ratio c/b with the concentration of adjacent codopants (Ag+Cl) in the sputtering target.

FIG. 16A and FIG. 16B show, respectively, (a) optical transmission spectra of the undoped CdS film and of the CdS:(Ag+Cl) films for the codopant concentrations of 0.5 to 5 at. %; and (b) Raman spectra of the undoped CdS film and of CdS:(Ag+Cl) films for concentrations of codopants from 0.5 to 5 at. %.

FIG. 17 illustrates the characterization of the electrical properties of CdS:(Ag+Cl) films by Hall effect as a function of the concentration of the adjacent codopants. The values of free carrier concentration (left vertical scale), mobility (first right vertical scale) and resistivity (second right vertical scale) are shown. The data correspond to measurements at room temperature.

FIG. 18A and FIG. 18B show, respectively, (a) photosensitivity (r=I_{Light}/I_{Dark}) of the CdS and CdS:(Ag+Cl) films as a function of the concentration of adjacent codopants; and (b) photocurrent of the film with 3 at. % of (Ag+Cl) in the dark and under illumination.

FIG. 19. Portion of the Periodic Table of the chemical elements where the concept of adjacent codopants is illustrated for the case of germanium (Ge). In this case, gallium is selected because it is the element with atomic number one unit lower than germanium and arsenic because it is the element with atomic number one unit higher than germanium. To achieve the incorporation of these elements, the compound gallium arsenide (GaAs) was used in the fabrication of the targets used to deposit the Ge:(Ga+As) films.

FIG. 20. Chemical composition of Ge and Ge:(Ga+As) films measured by energy dispersive spectroscopy as a function of different concentrations of adjacent codopants in the targets.

FIG. 21A and FIG. 21B show, respectively, the X-ray diffraction patterns of pure germanium and of Ge:(Ga+As) films grown at 300° C. with the indicated concentrations of adjacent codopants. (a) Without subsequent heat treatment; (b) after growth heat treated films for 30 min at a temperature of 550° C. in an inert Argon atmosphere. From the X-ray diffraction patterns the germanium lattice parameter (Eq. 2) was determined, the values of which are shown in FIG. 22.

FIG. 22. Values of the lattice parameter of germanium for undoped Ge and for Ge:(Ga+As) films as a function of the concentration of codopants. A horizontal line indicates the value of the lattice parameter for the Ge reference powder.

FIG. 23A, FIG. 23B, FIG. 23C and FIG. 23D, respectively, illustrate the optical transmission in the NIR-Vis-UV region of Ge and of Ge:(Ga+As) films for the different concentrations of codopants (a) without heat treatment, and (b) heat treated at 550° C. Raman spectra of the films (c) without heat treatment, and (d) heat treated at 550° C. for 30 minutes.

FIG. 24. Resistivity, mobility and free carrier density for Ge and Ge:(Ga+As) films obtained by Hall effect measurements of (a) as-grown, and (b) heat-treated films.

FIG. 25A and FIG. 25B show, respectively, photocurrent plots of the heat treated films of (a) Germanium and (b) Ge:(Ga+As) with 7 at. % of codopants. Lines 1 (red) correspond to the current under illumination and line 2 (black) to the current in the dark.

### DETAILED DESCRIPTION OF THE INVENTION

The present invention relates to a specific codoping method comprising the selection of impurities to be incorporated into a host material that modifies fundamentally its electronic properties such as the electrical conductivity and photoelectric response.

The present invention describes a method defined as adjacent compensated codoping (ACC). The proposed method consists in introducing two different types of impurities (codoping or dual doping) selected as follows: the atomic number of one of them higher by one (or two) unit(s) than that of one of the chemical elements forming the host material, and the other impurity with atomic number lower by one (or two) unit(s) with respect to other of the chemical elements forming the host material. The atoms of the host chosen to be substituted by the adjacent codopants shall be referred here as selected atoms.

ACC can be performed independently of the codoping process chosen to perform, examples include: codoping during crystal growth, codoping by using the Czochralski's method, methods where vapor phase epitaxy is used, codoping by processes such as electrodeposition, pulsed laser deposition, sputtering (DC or RF) and chemical spraying, diffusion and ion implantation, codoping by spray pyrolysis, codoping by any combination or modification of the listed techniques, and codoping by any other method to grow materials in bulk or to deposit thin or thick films. Codoping can also be done on rotating glasses where for example SiO₂ and dopants are mixed in a solvent on the surface of a wafer and with a rotating coating and then stripped and baked at a given temperature in the furnace at constant flow of nitrogen+oxygen.

The adjacent compensated codoping (ACC) method of the present invention involves a small offset of the ionic radius of the codopants; consequently, low lattice stresses occur, it also involves similarity between nucleus and inner electrons of the codopants and those of the host material, which promotes a tendency to produce shallow levels in the electronic forbidden band, the ACC involves using n+p codopants with a consequent reduction in the formation of charge compensating complexes, ACC is also characterized by a small mass difference between the codopants and the host compound, which results in a low perturbation of the host lattice vibrational properties of the host (phonons). Finally, ACC is characterized by a minimal electronegativity difference between codopants and host atoms, thus avoiding abrupt changes in the chemical bonds between codopants and host atoms.

In a preferred embodiment of the invention for performing the adjacent compensated codoping, the films of materials used here as examples were deposited by radio frequency sputtering on glass substrates.

The host material can be a multicomponent (one element, binary, ternary, quaternary, etc.) host material of a semiconductor compound with generic chemical formula AEGJ . . . , where AEGJ . . . represent chemical elements forming the compound; select any two chemical elements forming the compound A and G (one cation and one anion, both cations, or both anions) which have atomic numbers Z_{A} and Z_{G}; the host may as well be formed by a single element A. The host material can be a multi-elemental compound or an alloy. That is, it can be a single element semiconductor (such as Ge or Si), binary (such as CdTe, CdS or GaAs), ternary (such as CuInSe₂ or HgIn₂Te₄) or quaternary (such as InGaAsP).

The products of the adjacent compensated codoping (ACC) of the invention comprising the tested and exemplified growth method described in detail here or some other method that permits codoping, can be applied in semiconductor devices.

Other applications of ACC are as insulating materials that can be converted into superconductors if they can be successfully doped such as CsTIF₃, La₂CuO₄, and Nd₂CuO₄, as well as in materials that could be topological insulators, such as BaBiO₃, which require for this functionality a level of impurification such that the position of the Fermi level lies within the conduction band.

The ACC method f the invention can also be applied to improve impurification in organic materials through the incorporation of substitutional impurities, since at present mainly donor impurities of interstitial type are incorporated.

The ACC method of the invention can be used for the effective impurification of transparent conducting oxides.

The ACC method of the invention is useful for the impurification of organic-inorganic hybrid perovskites used in solar cell technology.

The ACC method of the invention can be applied in the impurification of “half-Heusler” type alloys: A^{III}B^{X}C^{V} (e.g., ScPtSb), A^{IV}B^{X}C^{IV} (e.g., ZrNiSn), A^{IV}B^{IX}C^{V} (e,g, TiCoSb) and A^{V}B^{IX}C^{IV} (e.g., TaIrGe) that can present important functionalities as thermoelectric materials or as transparent conductors.

Pursuant to the present invention a specific manner of selection of the codopants related to the chemical composition of the host material is established.

The proposed method consists of introducing two different types of impurities (codoping or dual doping) selected as follows: the atomic number of one of them higher by one (or two) unit(s) than that of one of the chemical elements forming the host material, and the other impurity with atomic number lower by one (or two) unit(s) with respect to another of the chemical elements forming the host material.

While single impurification (one impurity) of semiconductors is a known method that has been performed commonly since the last century, the use of two impurities per se has been little explored. The approaches in which such dual doping has been performed to date differ from ACC in the manner and intentionality of selecting the codopant elements as described below.

In ACC the impurities are selected from the chemical elements that are adjacent in the Periodic Table to elements forming the host material in order to affect as little as possible the crystalline structure, the local electric charge balance due to impurification, the chemical bonds of the host, the vibrational properties of the crystalline lattice (phononic properties), and (where applicable) to favor the formation of shallow electronic levels within the forbidden band of the host.

The ACC method of the invention achieves the above benefits by simultaneous incorporation of n-type and p-type impurities, in a one-to-one ratio, or close to it, of adjacent chemical elements in the Periodic Table, one heavier and one lighter as specified below, into the parent compound (host). The ACC method of the invention comprises selecting two impurities Q and X from the Periodic Table of the chemical elements comprising the codopants under the following schemes: (i) considering the selected chemical elements of the host A and G, impurity Q is the chemical element with atomic number Z_{A}−1 and impurity X is the chemical element with atomic number Z_{G}+1; other possible way to select the adjacent codopants is when the impurity Q is the chemical element with atomic number Z_{A}+1 and impurity X is the chemical element with atomic number Z_{G}−1; or (ii) considering the selected chemical elements of the host A and G, impurity Q is the chemical element with atomic number Z_{A}−2 and impurity X is the chemical element with atomic number Z_{G}+2; other possible way to select the adjacent codopants is when impurity Q is the chemical element with atomic number Z_{A}+2 and impurity X is the chemical element with atomic number Z_{G}−2; or (iii) considering the selected chemical elements of the host A and G, impurity Q is the chemical element with atomic number Z_{A}−1 and impurity X is the chemical element with atomic number Z_{G}+2; other possible way to select the adjacent codopants is when impurity Q is the chemical element with atomic number Z_{A}+2 and impurity X is the chemical element with atomic number Z_{G}−1.

In other example, when the host material is formed by a single element A, impurity Q and impurity X correspond to the chemical elements with atomic numbers Z_{A}−1 and Z_{A}+1; or with atomic numbers Z_{A}−2 and Z_{A}+2; or combinations of atomic numbers Z_{A}−1 and Z_{A}+2; or Z_{A}−2 and Z_{A}+1.

ACC is illustrated in the following additional example: for a generic binary compound AG formed with chemical elements with atomic numbers Z_{A} and Z_{G}, under the ACC method the material can be codoped simultaneously with impurities X and Y that have atomic numbers Z_{A}−1 and Z_{G}+1, respectively, that is impurities X have an atomic number lower by one unit than atoms A and impurities Y have an atomic number larger by one unit than atoms G; or with impurities Z_{A}+1 and Z_{G}−1, which means that impurities X have an atomic number larger by one unit than atoms A and impurities Y have an atomic number lower by one unit than atoms G. The concentration of impurities X and Y to be used shall depend on the functionality sought in the codoped material. In ACC the same criterion as in the previous point applies for choosing the codopants X and Y when the differences in atomic number of the adjacent codopants with respect to two atoms of the host compound differ by two units.

The combinations of codopants with Z+1 and Z−1, where one of the impurities is one atomic number unit higher than one atom of the host, and the other, one atomic number unit lower than other atom of the host to be substituted for, have been designated here as adjacent codopants, because of their adjacent position in the Periodic Table with respect to the substituted chemical elements forming the host material. Following the example of a binary compound, with this selection of impurities according to ACC, the following advantages over the hitherto used other forms of dual doping are promoted:

a) The stresses introduced in the host crystalline lattice due to the incorporation of adjacent compensated codopants are small. The crystalline lattice is expanded by impurities Z_{A}+1 (or Z_{G}+1) and contracted by impurities Z_{B}−1 (or Z_{G}−1), which generates a partial or full compensation of the stresses caused by the different ionic radii of the codopants with respect to those atoms in the host they substitute for.

b) The formation of charge compensating defects/complexes that semiconductors naturally tend to form when they reach their limit of density of free charge carriers they can handle is reduced. The simultaneous incorporation of n-type (donor) and p-type (acceptor) impurities at a one-to-one ratio (or close to it due to experimental or fabrication limitations) allows increasing the impurity density before the generation of compensating effects by the host. The beneficial effect on the electrical properties of the host will depend on the asymmetry in the relative energy position of the electronic levels due to the impurities, with respect to the conduction and valence band edges. That is, the effective final n- or p-type characteristics of the ACC material will be a function of the difference in activation energies of the n- and p-type codopants.

c) Adjacent codopants tend to generate shallow levels in the bandgap of the host. Since the inner part of the atom (inner electrons plus nucleus, or else the atom minus the valence electrons) of the adjacent codopants resemble the inner part of the selected atoms of the host material, the electronic levels of the impurities will tend to produce shallow levels in the bandgap [24], favoring the transfer of electrons to the conduction band and of holes to the valence band, thus improving the electrical conductivity of the host material.

d) The nature of the chemical bond (covalent, polar covalent or ionic) in the host material will not change abruptly by incorporating adjacent codopants. The use of adjacent codopants implies that the electronegativity difference between codopants and selected atoms in the host material is the smallest possible under this impurification scheme.

e) The crystalline lattice dynamics are not significantly affected by the use of adjacent codopants. Following the example of a binary semiconductor, since the atomic masses of the adjacent codopants differ slightly from the masses ma and mg of the selected atoms of the host material (if Z_{G}+1 adjacent codopants are used the mass difference is the minimum possible), both the vibrational dynamics of the crystalline lattice and any interaction of any pseudo particle (a free electron, for example) with the crystalline lattice (i.e., with phonons) will have similar characteristics to those of the material without codopants, thus avoiding the formation of localization effects that affect the movement of free charge carriers and, therefore, a decrease in electrical conductivity. That is, the vibrational modes induced by the impurities will be of the resonant type with respect to the vibrational modes of the host, as opposed to the local or bandgap modes that occur when the masses of impurities are substantially smaller or larger, respectively.

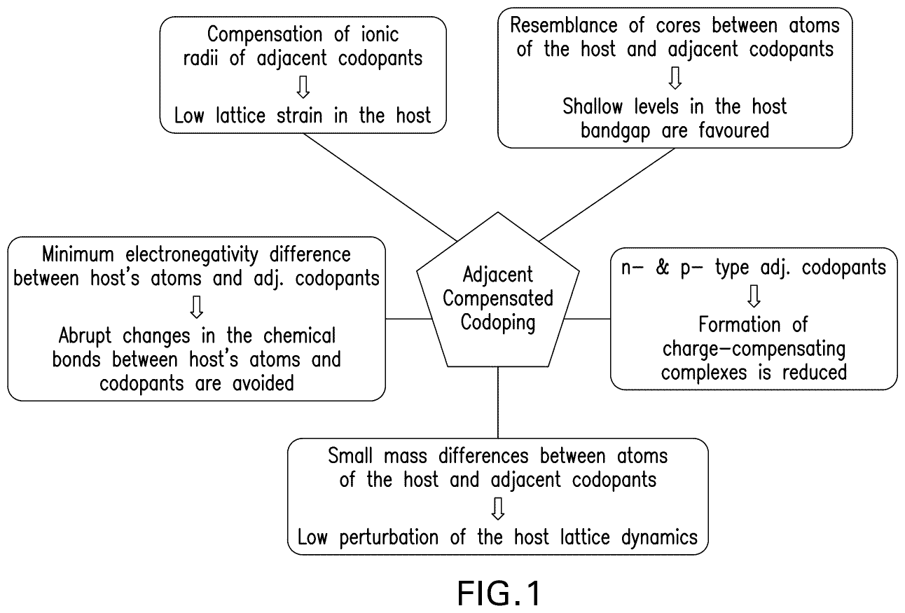

The novelty of the present invention lies precisely in the use of adjacent compensated codopants, and to all their effects described in (a)-(e), which have the potential to solve, total or partially, the doping problems already mentioned in (i)-(iv). That is, the disorder introduced in the host crystalline lattice through the effects described (a)-(c), is low compared to that which would be produced by using other types of (non-adjacent) codopants. This form of codoping has not been conceptualized to date. The main characteristics (advantages) and effects of Adjacent Compensated Codoping are shown graphically in FIG. 1.

Specifically, in the present invention the use of adjacent codopants refers to the incorporation of two impurities with atomic numbers in combinations of the type: Zᵢ±n and Zⱼ±m, with n,m=1, 2; the plus and minus signs taken in combinations +/− or −/+ for the two impurities; where Zᵢ and Zⱼ refer to the atomic numbers of chemical elements sought to be substituted for (host's selected atoms) in a multicomponent (one element, binary, ternary, quaternary) host material. In the case of a single-component material such as silicon, germanium or carbon, i=j applies. The combinations of adjacent codopants considered in this invention are thus of the type: Zᵢ+1 and Zⱼ−1; Zᵢ+2 and Zⱼ−2; or a combination Zᵢ+1 and Zⱼ−2. Thus, in semiconducting materials one of the codopants will tend to produce n-type conductivity and the other codopant will tend to produce p-type conductivity. This last characteristic gives rise to the term compensated in the name ACC, which by no means imply total electrical compensation by the codopants, as evidenced by the examples herein.

Additionally, one of the advantages that ACC shares with the type of codoping performed to date is the increase in solubility of impurities in the host material. It is worth mentioning, however, that due to the characteristics of the adjacent codopants it is to be expected that the increase in solubility of adjacent impurities for a given host material will be higher than that which would be obtained with a different selection of codopants. This is due to the similarities that the adjacent codopants have with the atoms that form the host material.

It is important to mention that historically the development and problems involved in the doping process to modify physical properties in materials has been focused on semiconductor materials; however, the applicability of ACC has the potential to solve current limitations in the development of other types of materials such as [25]:
Insulating materials that can become superconductors if they can be successfully doped such as CsTIF₃, La₂CuO₄, and Nd₂CuO₄.
Materials that could be topological insulators, such as BaBiO₃, which require for this functionality a level of impurification such that the position of the Fermi level falls within the conduction band.
Improve the current levels of impurification in organic materials by incorporating substitutional impurities, since currently generally interstitial donor impurities are incorporated.
Effective impurification of transparent conducting oxides. Most transparent materials in the visible (i.e. of large forbidden bandwidth) do not tolerate a high concentration of impurities without developing a structural reorganization (defects/complexes) that produces a significant free carrier compensation.
Impurification of organic-inorganic hybrid perovskites. Impurification of these materials is to date very difficult to carry out despite their great importance in solar cell technology. The efficiency achieved to date in this type of solar cells is over 25%, which was achieved in a relatively short development time.
The “half-Heusler” compounds A^{III}B^{X}C^{V} (e.g., ScPtSb), A^{IV}B^{IX}C^{V} (e.g., TiCoSb), A^{IV}B^{X}C^{IV} (e.g. ZrNiSn) and A^{V} B^{IX} C^{IV} (e.g., TaIrGe) may exhibit important functionalities as thermoelectric materials or as transparent conductors; however, their doping behavior is not understood, making them difficult to impurify efficiently in practice.

The results of the use of ACC in some semiconductors and the effect on their electrical and photoelectric properties will be shown below to demonstrate the advantages of the ACC method and its potential in the design and preparation of semiconductor materials for applications in various electronic and optoelectronic devices, such as high-efficiency solar cells, lasers, photodetectors and radiation detectors, among others.

### Method of Preparation:

In general, there are several methods for the fabrication of semiconductor materials, either to prepare bulk samples or in thin film form (thicknesses of the order of a some micrometers). In the present invention, by way of example, the technique of thin film growth by Radio Frequency Sputtering was used for the preparation of all the samples mentioned herein. The targets of the material to be deposited were made by pressing at room temperature mixtures of powders of the base material (host) and impurities (codopants) in certain atomic proportions, which are specified for each of the cases described. The powder mixture was placed inside a stainless-steel die which was pressurized in a hydraulic press to form a compact target 5 cm (2″) in diameter and 3 mm (⅛″) thick. By controlling the composition of the powder mixture, it is possible to control the concentration of impurities in the deposited films in a simple and reproducible way.

In each of the following examples of adjacent compensated codoping, the above procedure was followed for the fabrication of the targets.

### ACC Applied to Cadmium Telluride:

Cadmium telluride (CdTe) is one of the most widely used materials as absorbing layer in the fabrication of solar cells due to its high optical absorption coefficient (>10⁴ cm⁻¹) and whose bandgap (1.5 eV) is very close to the optimum value established by the Shockley-Queisser limit [26]. This material has been deposited by various techniques such as electrodeposition, pulsed laser deposition, sputtering and chemical spraying, among others [27, 28]. In particular, CdTe/CdS junctions have been used for the conversion of light into electricity with efficiencies on the order of 22% [26]. Attempts over the last 30 years to increase this value have included the use of new architectures, as well as the search for appropriate electrical contacts and appropriate dopants. Efficient impurification of cadmium telluride has had its particular difficulties when p-type material needs to be made, since low free carrier densities, typically not greater or of the order of 10¹⁵ cm⁻³, are obtained and because of the formation of unwanted secondary phases or metallic clusters [30, 31].

In this work, CdTe:(Ag+I) films were grown by RF sputtering at different substrate temperatures. In this case, silver and iodine correspond to the chemical elements that satisfy the ACC criterion for CdTe. By way of comparison, films of CdTe:Ag were also fabricated. The films were characterized, as described below, by XRD, UV-Vis and Raman spectroscopies, SEM and Hall effect.

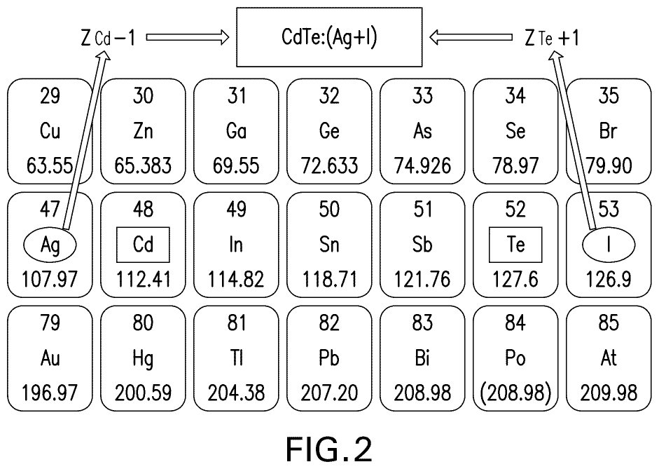

FIG. 2 illustrates the selection of the adjacent codopants silver (Ag) and iodine (I) for the case of CdTe. In this case silver is selected because it is the element with atomic number one unit lower than cadmium and iodine is selected because it is the element with atomic number one unit higher than tellurium. Next, it will be shown that the use of adjacent codopants (Ag+I) in CdTe allows (a) to obtain both n-type and p-type impurifications, depending on the concentration of codopants; (b) obtain free carrier concentrations in the range 10¹⁷−10¹⁸ cm⁻³ without the formation of undesired compounds or secondary phases; (c) obtaining low electrical resistivities between 1 and 10³ Ω·cm; and (c) highly efficient photoconductive characteristics, which allow envisioning their use in the fabrication of various optoelectronic devices with excellent performance. Notably, the photoelectric properties (photoconductivity) indicate that the incorporation of adjacent codopants (Ag+I) in CdTe increased considerably the recombination times of the electron-hole pairs generated by the light incident on the material, in such a way that it is possible to extract charge carriers to an external circuit before they are lost through recombination processes.

To achieve the incorporation of these elements, the compound silver iodide (AgI) was used in the fabrication of the targets used to deposit the CdTe:(Ag+I) films.

### Preparation of CdTe:(Ag+I)

CdTe:(Ag+I) ACC films were deposited by radiofrequency sputtering at a temperature of 275° C. on glass slide substrates with dimensions of 2.5 cm×7.5 cm. Deposition targets were prepared using CdTe powder (99.999% pure) and silver iodide (AgI) powder (99.999% pure), the latter at concentrations of 0.5, 1.0, 3.0, 4.0, 5.0, 6.0 and 7.0 at. %. Specifically, codoping with z at. % of AgI means z at. % of silver and z at. % of iodine. Deposits were performed using argon as working gas at a pressure of 1 mTorr. A radio frequency power of 35 W was applied to the target and the target-substrate distance was 8.5 cm. The substrate was rotated during the films' growth at a frequency of 50 rpm. Prior to film deposition, the target surface was pre-sputtered for 5 min to remove surface contaminants.

Properties of CdTe:(Ag+I) films.

### Chemical Composition

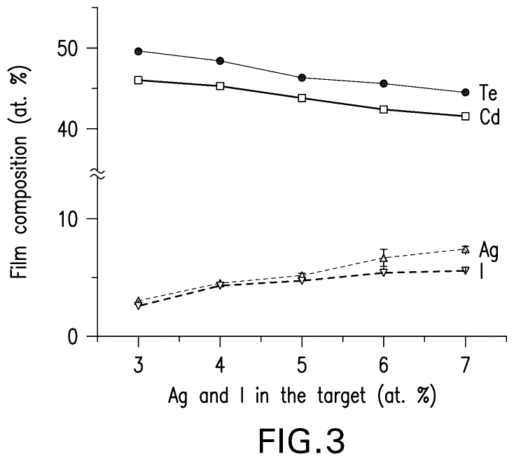

FIG. 3 shows the chemical composition of the films obtained by energy dispersive spectroscopy (EDS) as a function of the concentration of AgI in the target from which the films were deposited. As can be seen, the concentration of the codopants (Ag+I) in the films closely follows the concentration used in the targets. Naturally, as the concentration of codopants increased, the concentration of the host atoms Cd and Te decreased proportionally. A slightly lower cadmium concentration than tellurium is also observed, which is partially offset by a higher silver concentration. This is to be expected since, through the ACC process, the substitution of cadmium atoms by silver atoms is sought, while the other substitution sought is tellurium by iodine.

### Structural Properties

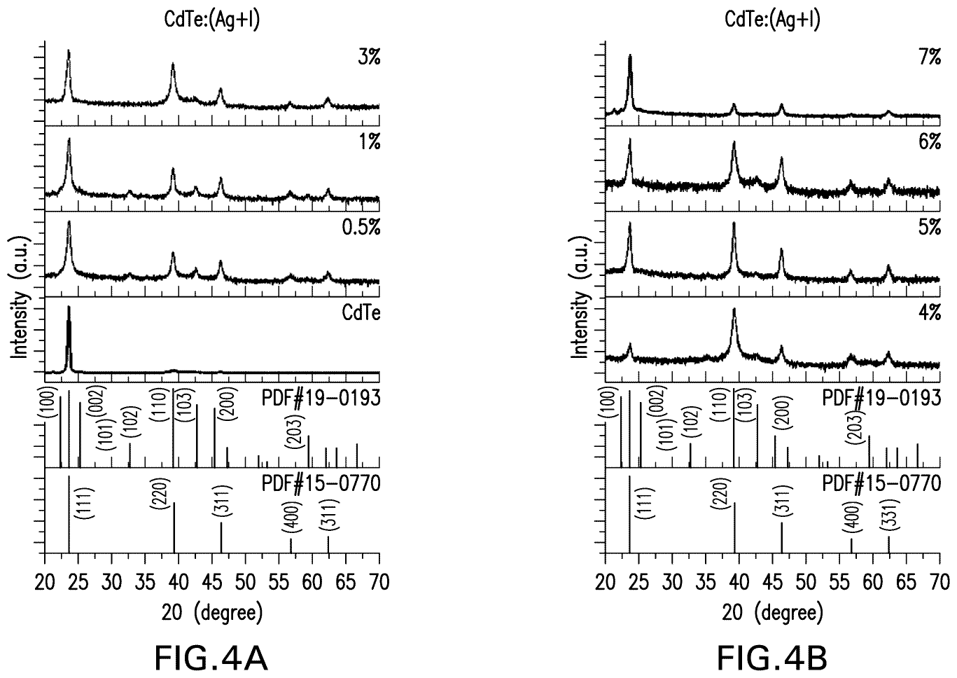

FIGS. 4A and 4B show, respectively, the X-ray diffraction patterns of pure CdTe films and of films with different concentrations of (Ag+I). For reference, the powder pattern data of CdTe for cubic zincblende-type (PDF No. 15-0770) and hexagonal wurtzite-type (PDF No. 19-0193) structures are presented at the bottom of each panel. PDF refers to the Powder Difraction File published by the International Centre for Diffraction Data (ICDD). As can be seen, all the diffraction peaks obtained correspond to crystalline planes of CdTe. That is, there are no additional peaks that could evidence the presence of secondary compounds or undesired segregations. This shows that the silver and iodine atoms were completely incorporated into the crystalline lattice of CdTe without presenting solubility problems up to the highest concentration used (7% at.).

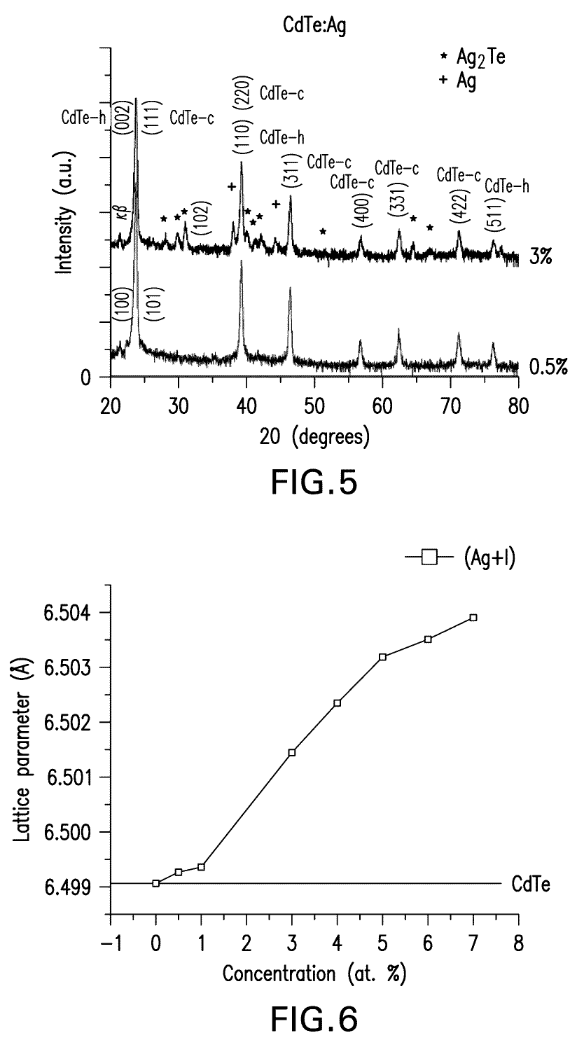

It is relevant to show that, if only silver is used as impurifying agent in CdTe, the deposition of films in the same conditions as those used for the CdTe:(Ag+I) films leads to the formation of undesired secondary compounds such as Ag₂Te and silver clusters. FIG. 5 shows the X-ray diffraction patterns of CdTe films grown at 275° C. using targets with 0.5 and 3.0 at. % silver. The appearance of peaks corresponding to silver telluride (Ag₂Te) and metallic silver (Ag) evidences the formation of unwanted by-products when using only one dopant. The letters c and h for CdTe refer to the cubic and hexagonal phases, respectively. Indeed, diffraction peaks corresponding to Ag₂Te and silver clusters are clearly observed in the sample that was grown with 3 at. % of silver in the sputtering target. The above results clearly indicate that the ACC method with (Ag+I) prevented the formation of such unwanted by-products.

The presence of stresses(S) in the crystalline lattice of the CdTe host can be evaluated from the change in the lattice parameter caused by the incorporation of the codopants. That is, by determining:

$$S = \frac{Δ a}{{a}_{0}} = \frac{\vert {a}_{c o d} - {a}_{0} \vert}{{a}_{0}} \times 100 \qquad ( 1 )$$

Where do is the lattice parameter of pure CdTe and α_{cod} is the lattice parameter of codoped CdTe. Since the stable phase of CdTe is the cubic zincblende-type phase, for the calculation of the stresses present in the films, the position of peak (311) of this phase was selected from the X-ray diffraction patterns in FIG. 5 to determine the value of the lattice parameter using the Bragg relation:

$$n λ = 2 d sin θ \qquad ( 2 )$$

where n is the diffraction order (n=1 in this case), λ is the X-ray wavelength (1.5406 Å for the copper source), d is the interplanar distance and θ the diffraction angle of the (311) planes. The latter varies slightly with codopant concentration.

TABLE 1
Values of the lattice parameter a of the cubic phase of CdTe and crystalline lattice stress
(Eq. 1) in the CdTe:(Ag + I) films as a function of the concentration of AgI in the target.

| | Concentration of (Ag + I) in the target (at. %) | | | | | | | |
|---|---|---|---|---|---|---|---|---|
| | 0 | 0.5 | 1.0 | 3.0 | 4.0 | 5.0 | 6.0 | 7.0 |
| Lattice parameter a | 6.4990 | 6.4992 | 6.4993 | 6.5014 | 6.5023 | 6.5031 | 6.5035 | 6.5039 |
| (Å), cubic phase | | | | | | | | |
| S (%) | 0 | 0.003 | 0.004 | 0.036 | 0.050 | 0.063 | 0.069 | 0.075 |

Table 1 shows the values of the percentage of stress (Equation 1) introduced in the crystalline lattice of CdTe by the incorporation of (Ag+I). As can be observed in Table 1, the stresses are less than 0.1% in all cases, which confirms that under the ACC scheme the crystalline lattice of the host is modified only slightly.

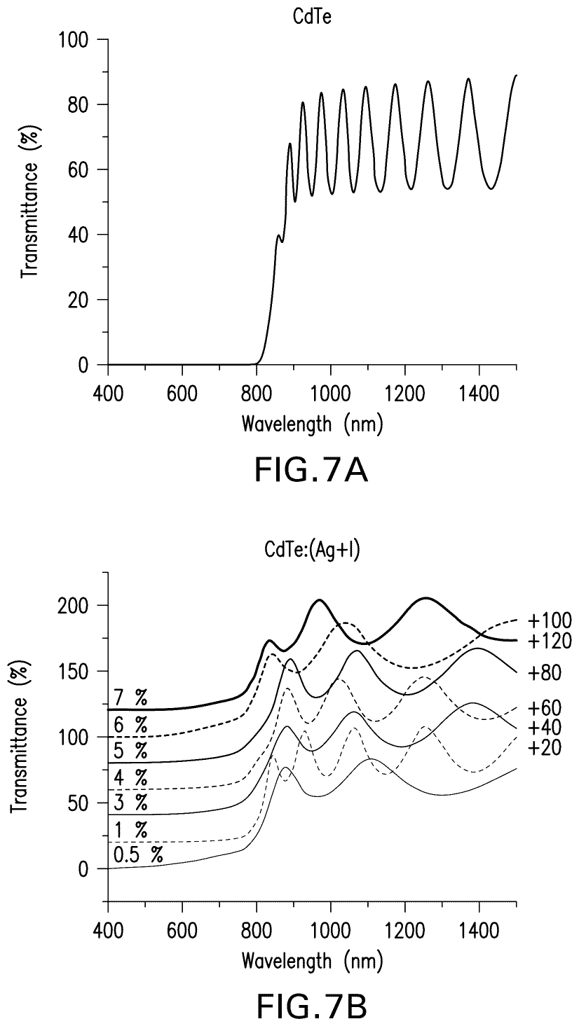

The changes in the lattice parameter of CdTe are shown graphically in FIG. 6, where the values of the lattice parameter in the CdTe:(Ag+I) films are shown as a function of the concentration of AgI in the target.

### Optical Properties

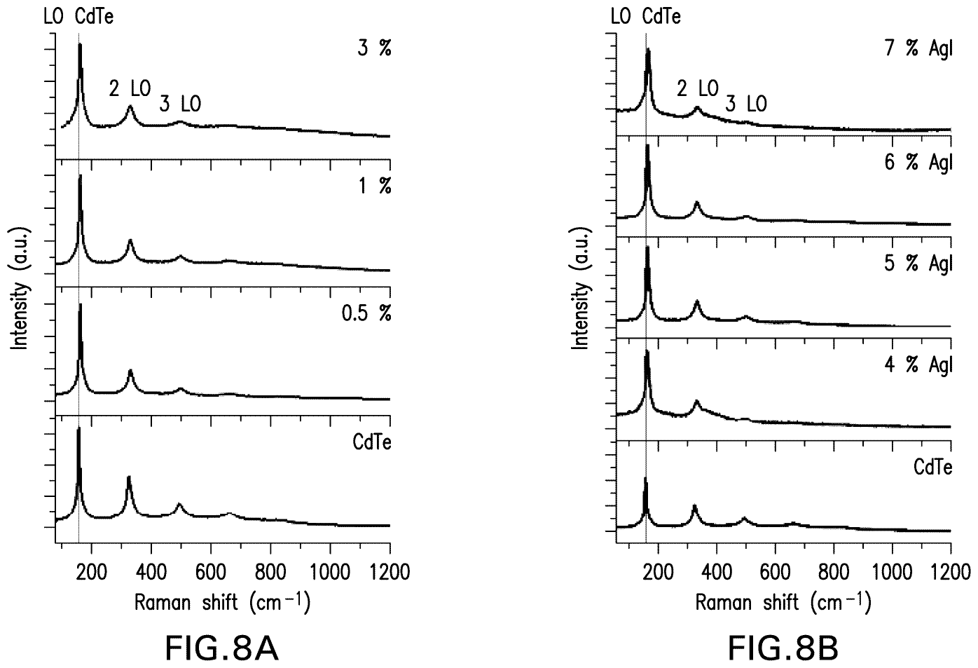

The optical properties of the CdTe:(Ag+I) films were evaluated by IR-UV-Vis optical transmission measurements in the 400 to 1500 nm range as illustrated in FIGS. 7A and 7B. As can be seen, the absorption edge of the codoped films remained around 800 nm (FIG. 7B), analogous to that of pure CdTe (FIG. 7A), regardless of the amount of AgI in the target. This indicates that the optical absorption properties were not significantly modified with ACC.

### Vibrational Dynamics of the Crystalline Lattice

Raman spectroscopy allows measuring the vibrational frequency of the normal modes of the atoms in the crystalline lattice of a material. This technique is a sensitive method to determine changes in the vibrational dynamics induced by defects such as impurities in the host lattice, which are characterized by having atomic masses different from those of the atoms of the host and by producing changes in the chemical bonds. These two modifications can affect, to a greater or lesser degree, the frequency of the normal vibrational modes of the host material and generate vibrational modes different from those of the pure material.

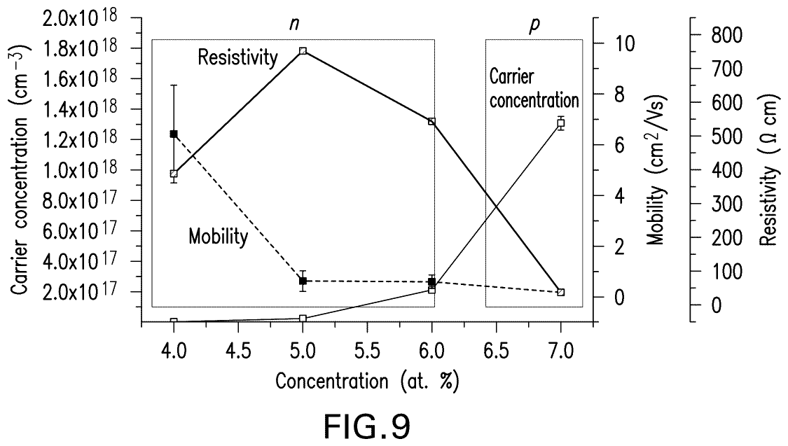

FIGS. 8A and 8B show the Raman spectra of the CdTe:(Ag+I) films for the films with different concentrations of codopants. In all cases, the optical longitudinal (LO) mode of pure CdTe is observed, as well as its harmonics up to third or fourth order. The measurements were performed in a Horiba spectrometer model HR Evolution. The appearance of harmonics of the LO modes has been associated with high crystalline quality in materials [32], so it can be concluded that the incorporation of codopants did not affect the crystalline quality of the host in an significant way.

The Raman spectra of the CdTe:(Ag+I) films are analogous to those of CdTe without dopants. As can be noted, no additional peaks or other changes are observed in the Raman spectra, demonstrating that the ACC did not affect significantly the vibrational dynamics of the CdTe host. The only observable change is a slight shift to higher frequencies of the optical longitudinal mode. The maximum shift was obtained for the sample with 7 at. % of (Ag+I), which was only 9 cm^{-1.}

That is, for the maximum concentration of adjacent codopants (7 at. %) the effect on the vibrational dynamics (phononic properties) of the host CdTe was minor, and without the appearance of additional peaks that would evidence the presence of unwanted secondary compounds.

These results are relevant because it is shown that the adjacent codopants (Ag+I) did not affect the phononic properties (sensitive to differences in atomic masses and bond types) since the adjacent codopants with atomic masses and electronegativities differ little (the minimum possible in this case, FIG. 2) with respect to the masses and electronegativities of the host material atoms (Cd and Te).

### Electrical Properties

The electrical properties of the CdTe:(Ag+I) films were determined by Hall effect measurements at room temperature. Measurements were performed for samples with adjacent codopant concentrations between 4 and 7 at. %. In the case of films with codopant concentrations below 4 at. % it was not possible to perform the measurements because their electrical resistivity was high and out of the range of the equipment (>10⁷ Ω·cm).

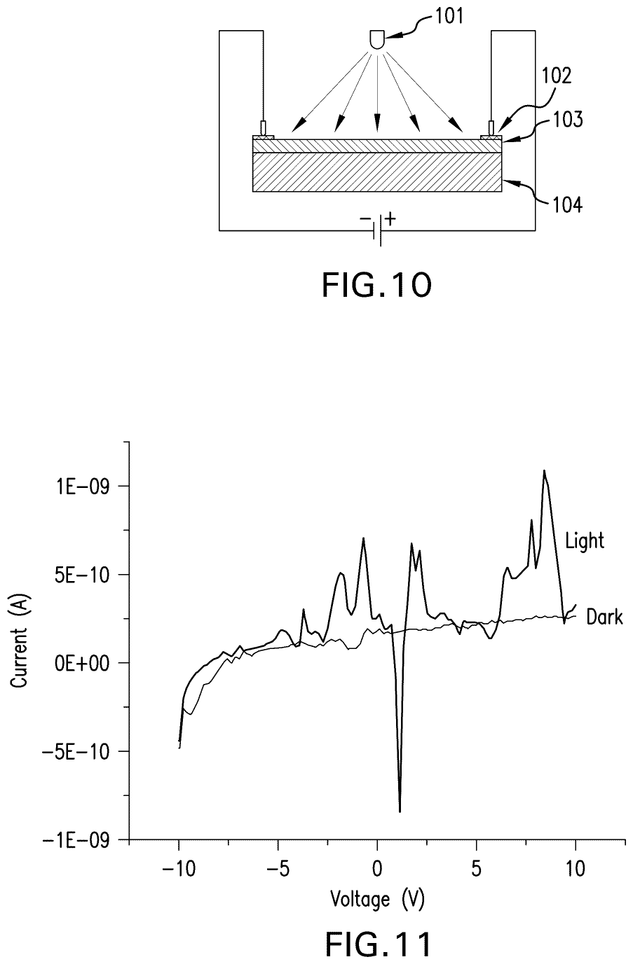

FIG. 9 shows the values of the free charge carrier density, mobility and resistivity. The values of resistivity ranged from 36 to 751 Ω·cm.

The values of the free carrier density ranged from 8×10¹⁵ cm⁻³ to 2.1×10¹⁷ cm⁻³ for the n-type material and it was 1.3×10¹⁸ cm⁻³ for the p-type material (7 at. %).

The values of the mobility ranged from 0.14 to 6.4 cm²/Vs, which are typical for polycrystalline semiconductor films.

A remarkable aspect is that for the concentrations of (Ag+I) between 4 and 6 at. % the material is n-type and for the concentration of 7 at. % the material had p-type characteristics. This will allow selecting the type of conductivity (n or p) required for a specific application.

It is relevant to mention that under ACC it was possible to exceed substantially the typical maximum value (˜10¹⁵ cm⁻³) that has been obtained to date for the concentration of free charge carriers in p-type CdTe.

For the p-type sample of CdTe:(Ag+I), with 7 at. % of adjacent codopants, the free hole density was 1.3×10¹⁸ cm⁻³, three orders of magnitude higher than the limit that has been achieved to date with other impurification methods.

This indicates that the formation of natural charge compensating defects in p-CdTe was reduced substantially allowing to reach the value of 1.3×10¹⁸ cm⁻³. This opens the possibility for improving largely the efficiency of CdTe-based solar cells, since the low values of free hole density in this material (˜10¹⁵ cm⁻³) has been one of the bottlenecks to improve the efficiency of photovoltaic cells using CdTe as absorbing layer [29].

It also highlights the fact that the resistivity of CdTe (˜10⁷ Ω·cm) was reduced by 5 to 6 orders of magnitude, which shows that with ACC there was a considerable increase in the electrical conductivity of the material by avoiding the formation of deep levels within the forbidden band, a phenomenon that makes impurification processes inefficient.

### Photoconductivity

The photoconductive response of a material is an important property for various applications in the area of optoelectronics. The change in electrical conductivity when light impinges on a semiconductor is due to the photogeneration of electron-hole pairs, which contribute to the electric current when a voltage is applied.

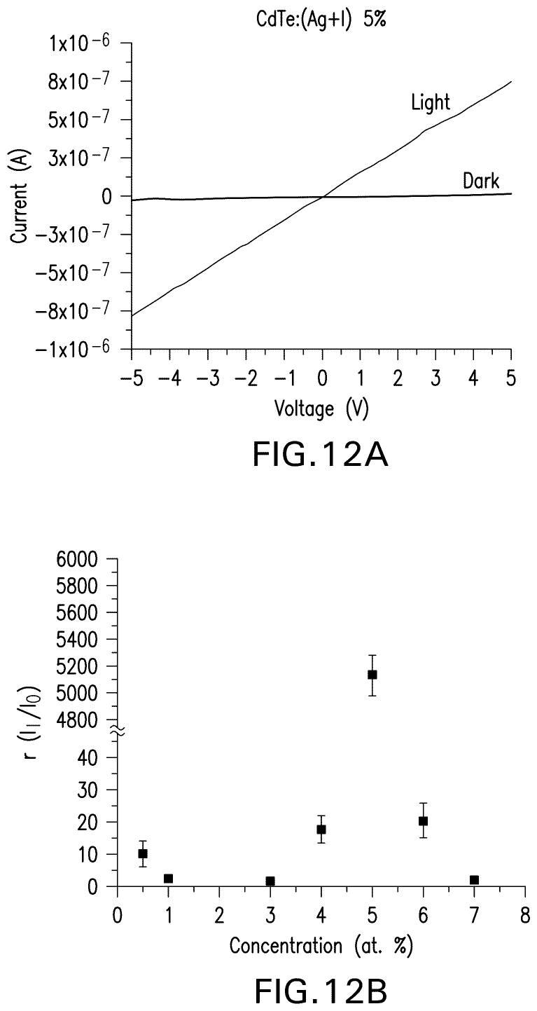

Next, it will be shown that the ACC in CdTe transformed this material from having no photoconductive response, to increasing the value of the current under illumination up to 3 orders of magnitude with respect to the value of the current in the dark. FIG. 10 illustrates the photoconductivity experiment under constant illumination. In these experiments, a white light lamp (100-watt Xenon lamp), with an irradiance calibrated to shine on the sample's surface with 100 mW/cm², was used as light source. This value of illumination power was chosen because it is used to simulate solar irradiance when evaluating solar cells.

Photoconductivity with Constant Illumination

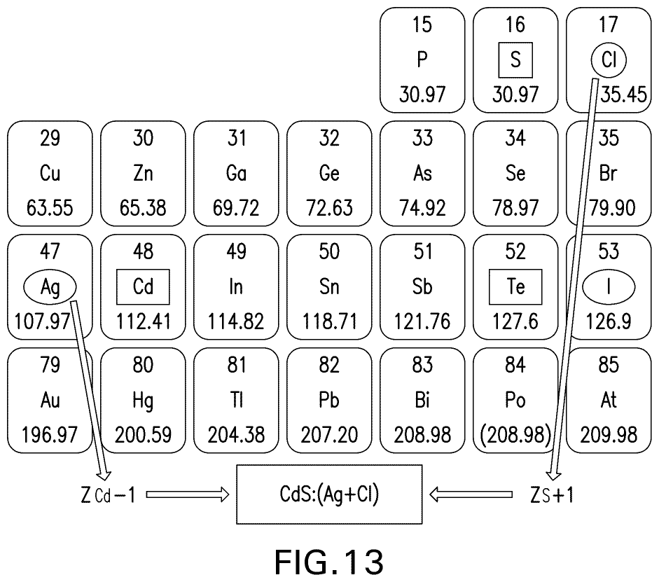

FIG. 11 shows the current response when applying a voltage between −10 and +10 V to the undoped CdTe film under illumination and in dark. As can be seen, the current had basically no change under illumination. In both cases (under illumination and in the dark) the measured current was at noise level (<nA) due to the high resistivity of the undoped CdTe.

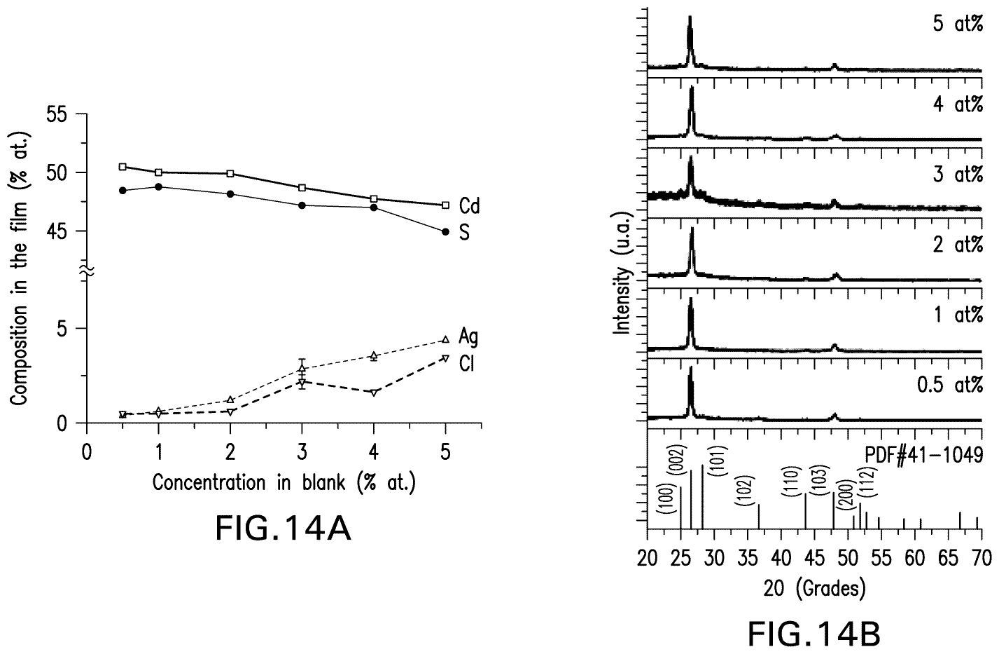

In both cases the values of the electrical current were at noise level (<nA) due to the high resistivity of the material. On the other hand, the CdTe:(Ag+I) films presented an excellent photoconductive response, as shown in FIG. 12A. The film with 5 at. % of (Ag+I) had the highest photocurrent. FIG. 12A compares for this sample the values of the current in the dark and under illumination when applying a voltage from −5 to +5V. To evaluate the photoconductive response of the ACC films, FIG. 12B shows the values of photosensitivity defined as [32]:

$$r = {I}_{L} / {I}_{O} , \qquad ( 3 )$$

where IL is the value of the current at illumination and I₀ is the value in the dark, for a voltage of +5V. As can be seen, the films codoped with 4, 5 and 6 at. % of (Ag+I) presented the best photosensitivity. In particular, it is noted that for the sample with 5 at. % the current under illumination was almost 5200 times higher than the value under dark conditions. This property is potentially very useful for applications in optoelectronic devices such as photovoltaic cells and photodetector devices. As can be seen in FIG. 12B, the photosensitivity of the CdTe:(Ag+I) films is a function of the concentration of the codopants Ag+I. The dependence of the photosensitivity on the concentration of traditional codopants has been previously observed in cases such as ZnO:(N+Te) [33]. An important difference between ZnO:(N+Te) and CdTe:(Ag+I) is that the codoping of ZnO with (N+Te) produced an increase in the resistivity of the material, unlike the ACC of CdTe:(Ag+I), for which the resistivity decreased by 5 to 6 orders of magnitude with respect to that of pure CdTe. Note the change of scale on the vertical axis in FIG. 12B for the 5 at. % concentration.

These results for the case of CdTe demonstrate the potential advantages of the ACC method.

In general, the physical properties that were significantly improved were: electrical resistivity, free carrier density and photoconductivity. These three characteristics have a high potential for applications in optoelectronic devices.

### ACC Applied to Cadmium Sulfide Films

Cadmium sulfide (CdS) is a II-VI semiconductor widely used as a window layer in various solar cell technologies (based on CdTe, or CuInSe₂ or hybrid perovskites). CdS is also known for its photoconductive properties [34, 35]. The intention of applying ACC to CdS (in addition to determining/studying its compositional, structural, phononic and electrical properties) was to determine whether ACC would improve the inherent photoconductive capabilities of the pure material. As will be shown below, the photoconductivity of CdS was further improved by applying the ACC approach.

### Preparation of CdS:(Ag+Cl)

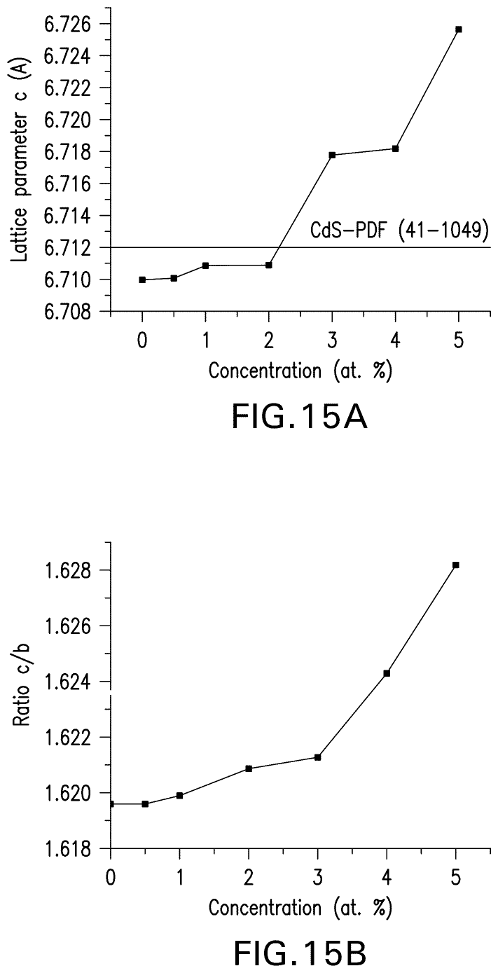

CdS films without impurities and codoped under the ACC scheme were deposited at a substrate temperature of 250° C. on glass slides. In this case the adjacent codopants were silver and chlorine (FIG. 13). The deposition targets were prepared using CdS powder (99.999% pure) and the compound silver chloride (AgCl) as source of silver and chlorine with different concentrations of codopants. The CdS:(Ag+Cl) films were grown from targets with AgCl concentrations of 0.5, 1.0, 2.0, 3.0, 4.0 and 5 at. %. Specifically, codoping with z at. % of AgCl means z at. % of silver and z at. % of chlorine.

### Properties of CdS:(Ag+Cl) Films

### Chemical Composition and Structural Properties

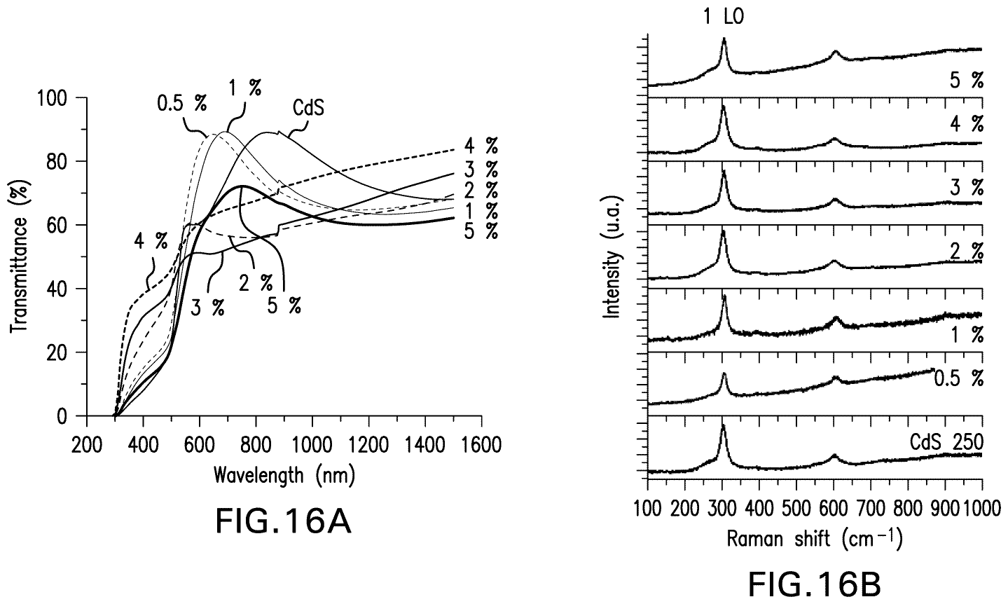

FIG. 14A shows the chemical composition of the films as a function of the concentration of AgCl in the target. As can be seen, the concentrations of Ag and Cl are very similar in the target and in the films. The concentrations of S and Cd decreased proportionally with increasing concentrations of the codopants.

FIG. 14B shows the X-ray diffraction patterns for each concentrations of codopants and for the pure CdS film. In all cases, the crystalline structure was hexagonal wurtzite-type, identified by the CdS powder reference PDF #41−1049 shown at the bottom panel. No additional peaks to those of cadmium sulfide were detected, indicating that Ag and Cl atoms were incorporated into the crystalline lattice of CdS without forming aggregates of different compounds. The similarity of the diffractograms for all concentrations of adjacent codopants may be noticed.

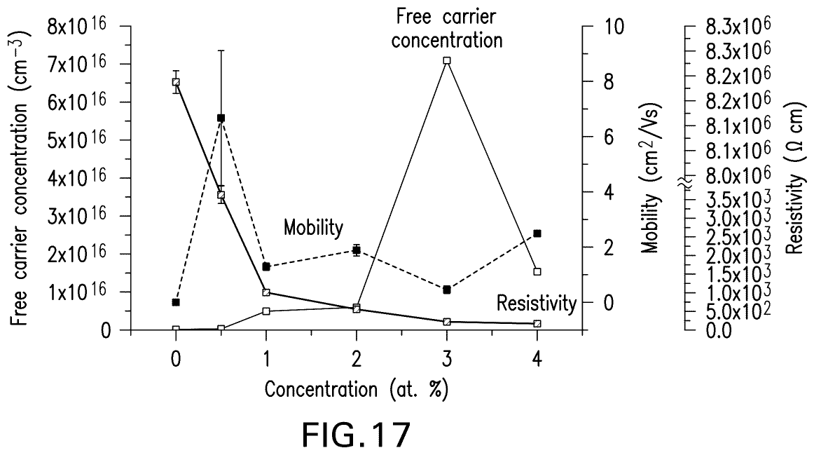

From the X-ray diffractograms, the values of the lattice parameter c of the hexagonal-wurtzite structure were determined using the Bragg's law (Eq. 2). These values for the undoped CdS and for the CdS:(Ag+Cl) films are shown in FIG. 15A for the different concentrations of adjacent codopants. From Equation 1, the value of the induced stress, determined from the change in the c-parameter under the ACC scheme, was calculated to be less than 0.2% in all cases. This shows that the stress induced by the incorporation of adjacent codopants is remarkably small. Similarly, the change in the ratio c/b was low, less than 0.5% for all cases, FIG. 15B. That is, the use of adjacent codopants modified only slightly the interatomic spacing of the host CdS.

### Optical and Vibrational Properties

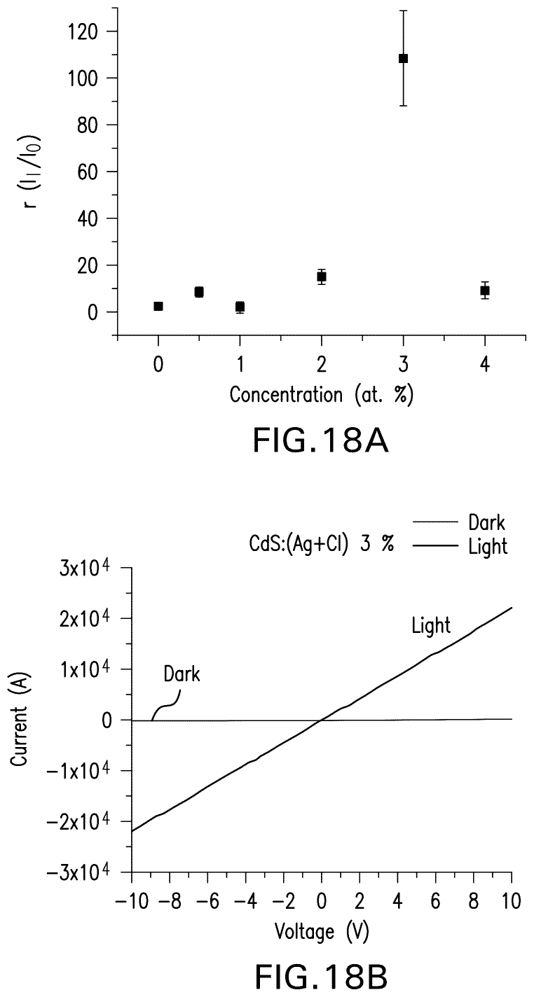

The effect on the optical properties is shown in FIG. 16A. The absorption edge was unchanged with respect to that of the undoped CdS film.

FIG. 16B shows that the crystalline lattice dynamics of the host material remained unchanged upon the incorporation of adjacent codopants. Indeed, the optical longitudinal mode frequency of the CdS remained without noticeable changes up to 5 at. % of adjacent codopants.

### Electrical Properties

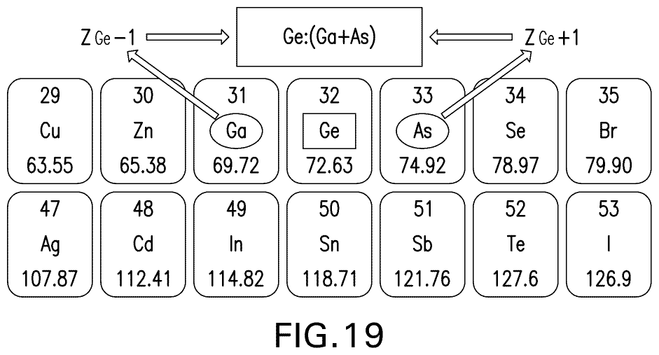

Through room temperature Hall effect measurements, the electrical properties of the CdS and CdS:(Ag+Cl) films were determined. The results are shown in FIG. 17. The incorporation of (Ag+Cl) improved the electrical properties of CdS. That is, the resistivity was reduced by four orders of magnitude, the free carrier density increased and the mobility also improved with respect to the undoped CdS.

### Photoconductivity

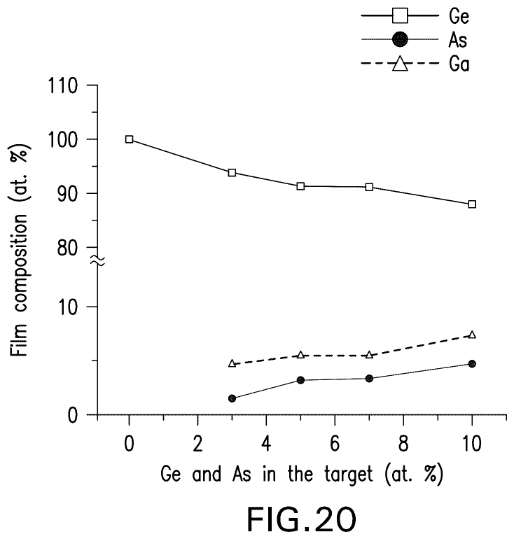

As mentioned above, CdS is a material that is known for its photoconductive properties [34, 35]. The photosensitivity (r=I₁/I₀, Equation 3) measured for the undoped CdS samples had a value of r=4. The data in FIG. 18a show that, far from damaging the photoconductivity of CdS, ACC improved that property in the films by incorporating the adjacent codopants (Ag+Cl).

This indicates that the presence of the adjacent codopants (Ag+Cl) modifies the electronic properties of CdS such that the photogenerated electron-hole pairs have longer lifetimes than those of pure CdS, producing photocurrents ˜115 times higher than the value in the dark. FIG. 18B shows the values of photocurrent for the CdS:(Ag+Cl) film with 3 at. %

In summary, ACC applied to CdS produced a material with minimal alterations in its crystalline structure, optical properties and lattice dynamics. On the other hand, the resistivity was reduced by up to four orders of magnitude, while the mobility and free carrier density were improved. From the point of view of photoconductivity, far from damaging this inherent property of pure CdS, it increased more than 100 times when the concentration of adjacent codopants was 3 at. %

### ACC Applied to Germanium Films

Germanium is a semiconductor of group IV (14) of the Periodic Table whose properties have been studied extensively, almost parallel to those of silicon [36]. Its main uses today include infrared detectors, optical fibers, uses in polymer catalysis, and in electronic and solar panels [37]. Given its importance and the characteristics of being a group IV mono elemental semiconductor, with chemical bonding of covalent type (different from the previous II-VI compounds that are polar covalent) and indirect bandgap (CdTe and CdS are direct bandgap), this material was selected to investigate the effect of ACC on its physical and electronic properties.

### Preparation of Ge:(Ga+as)

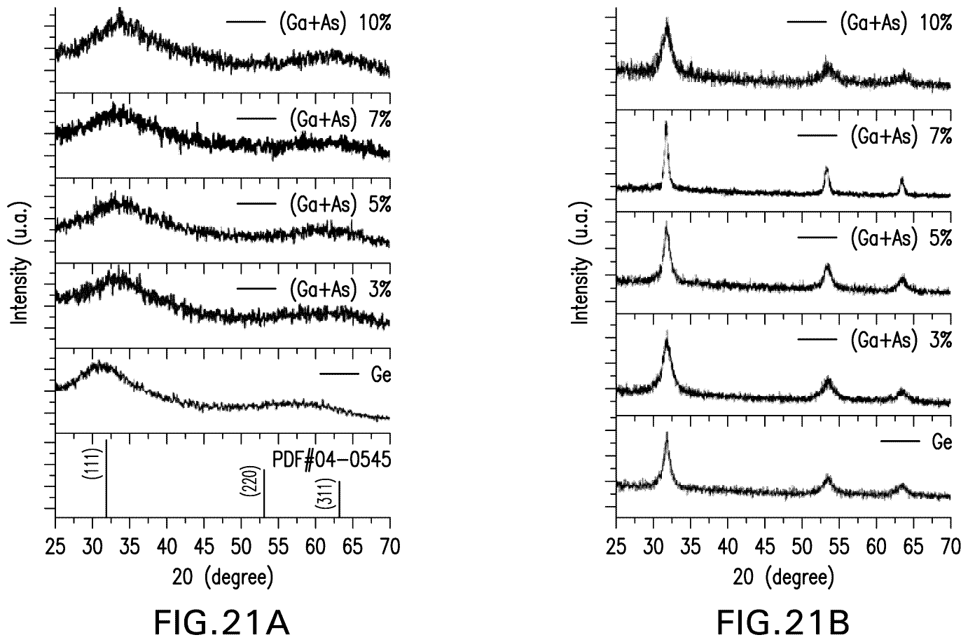

Germanium films were deposited in pure and codoped form under the ACC method at a temperature of 300° C. on glass microscope slides substrates. The films grown under these conditions produced films with amorphous structure. To determine the properties in polycrystalline films, some samples were subsequently thermally annealed in an inert argon atmosphere at 550° C. for 30 min. For germanium, the adjacent codopants were arsenic and gallium, as illustrated in FIG. 19. To achieve this adjacent codoping, the compound gallium arsenide (GaAs, 99.999% pure) was used as source of Ga and As to fabricate the targets (Ge, 99.999% pure) with codopants concentrations of 3, 5, 7 and 10 at. %. In this case, codoping with z at. % of GaAs means (z/2) at. % of gallium and (z/2) at. % of arsenic.

### Properties of Ge:(Ga+as) Films

### Chemical Composition

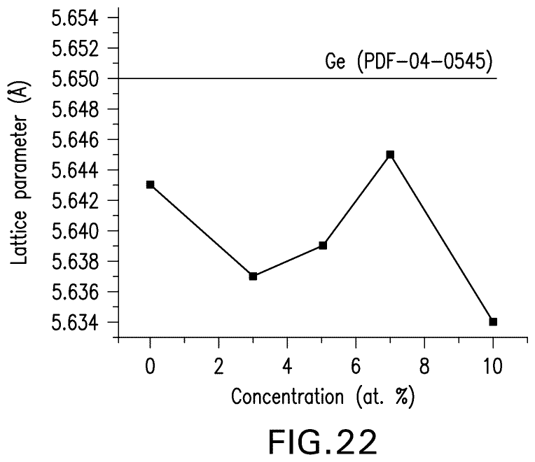

FIG. 20 shows the chemical composition of the films. As can be observed, the concentration of codopants in the films increased proportionally to their concentration in the target, although for the concentration of 10 at. %, it was lower than the nominal concentration in the target.

### Crystalline Structure

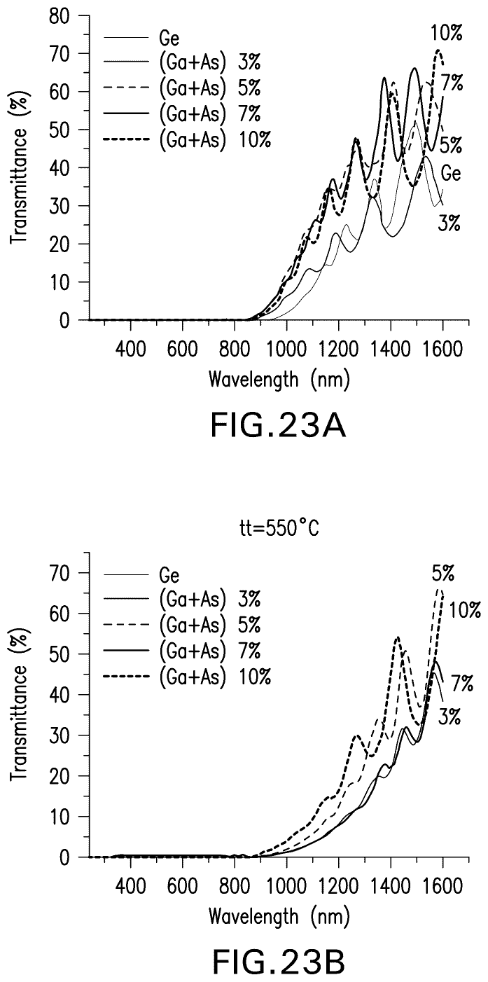

FIG. 21A shows the X-ray diffraction patterns of germanium films without heat treatment (as-grown). For reference, the lower panel in the figure shows the intensities and positions of the diffraction peaks of the reference powder pattern for this material (PDF #04-0545). It is observed that all samples grew with amorphous-type structure. Upon heat treatment, FIG. 21B, the films achieved some crystallization with the best crystallinity (in terms of the smallest full width at half maximum (FWHM) of the diffraction peaks) obtained for the film with 7 at. % of (Ga+As). It is important to note that at any concentration, no additional peaks were obtained that could evidence the formation of undesired secondary compounds.

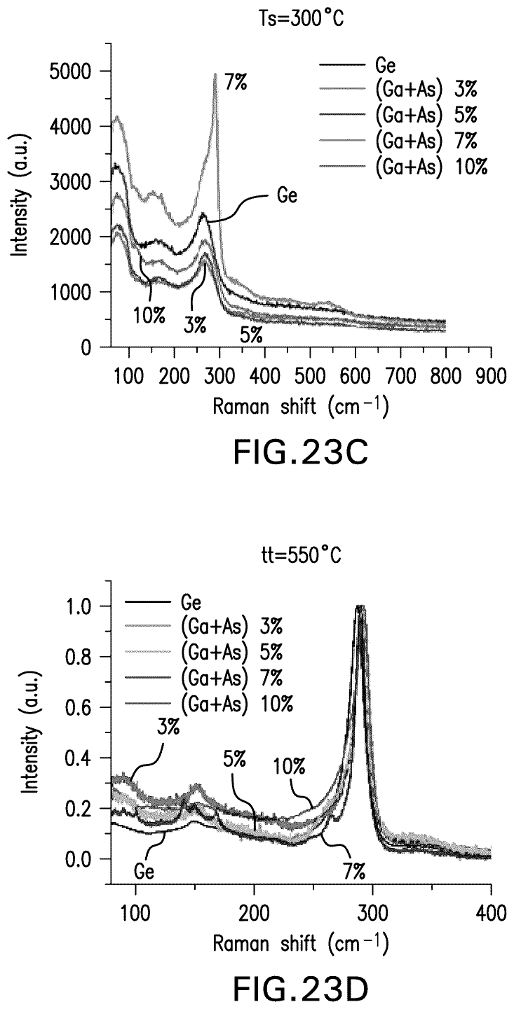

From the X-ray diffraction patterns, the lattice parameter of germanium was determined (Eq. 2), whose values are shown in FIG. 22. To evaluate the stress produced in the germanium lattice by the adjacent codopants, Equation 1 was used. In all cases the stresses were less than 0.16%, which shows that the ACC method produced a minimum perturbation to the crystalline lattice of the host Ge material.

### Optical and Vibrational Properties

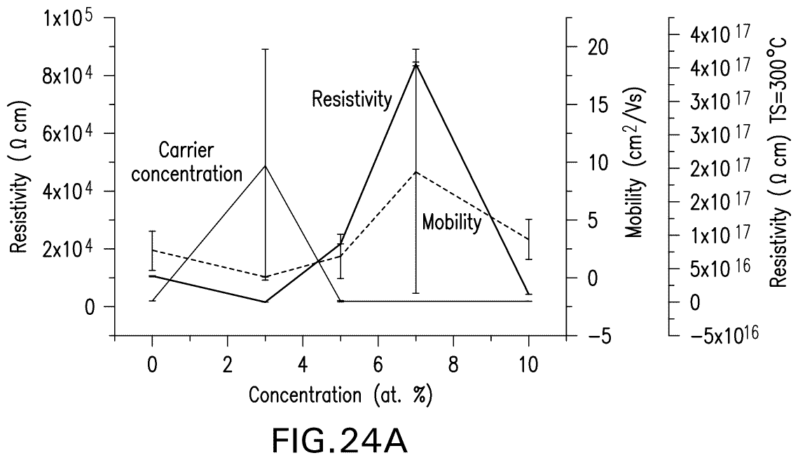

The optical transmission in the NIR-Vis-UV region of the films with and without heat treatment is shown in FIGS. 23A and 23B, respectively. In congruence with the X-ray diffraction results, no additional signals or behaviors associated with the formation of secondary compounds were detected. The differences in the position (wavelength) of the transmission edges were due to the different thicknesses of the films. That is, the ACC did not affect to a noticeable extent the optical properties of germanium. The Raman spectra of the films are shown in FIGS. 23C and 23D for the samples without (amorphous) and with heat treatment (polycrystalline), respectively. For the codoped amorphous samples, it is observed that the signal is very similar to that of the undoped germanium. Only for the film with 7 at. % adjacent codopants the spectrum presents a peak more defined and closer in frequency to that of monocrystalline Ge (300 cm⁻¹) [38], which is indicative that this film has a higher ordering to first neighbors than the rest of the films. After heat treatment, and as a consequence of the crystallization caused by it, the Raman signal of the films becomes better defined and its frequency approaches that reported for monocrystalline Ge. In the case of the film with 7 at. %, some additional low intensity peaks are observed whose frequency is close to peaks related to germanium with tetragonal structure [39]. The broad mode centered at 155 cm⁻¹ corresponds to amorphous germanium (see spectrum of the undoped Ge film).

### Electrical Properties

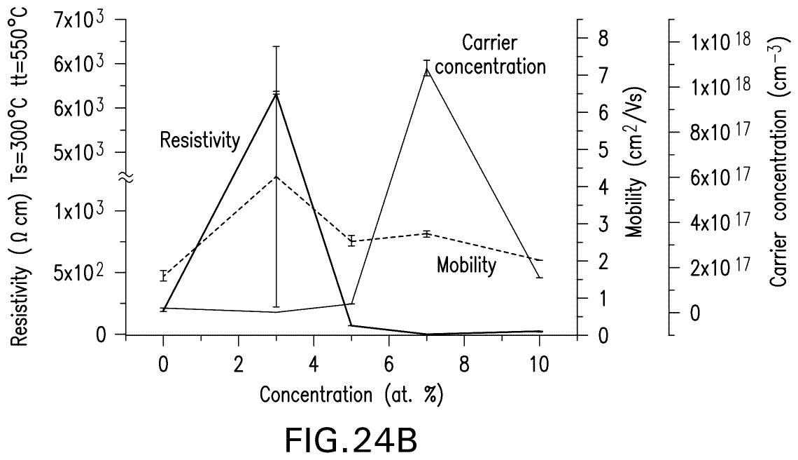

The values of resistivity, mobility and free charge carrier density for the amorphous samples (without heat treatment) are shown in FIG. 24A. Unlike the previous cases, these three charge transport parameters were not significantly improved by incorporating adjacent compensated codopants. This behavior, however, is to be expected due to the atomic disorder inherent in the amorphous matrix. Under these circumstances, it was not possible to improve the electrical properties of this type of material because of the large density of defects of the amorphous structure. In the case of the heat-treated polycrystalline films, FIG. 24B, ACC allowed to reduce the resistivity from 178.1 to 2.1 Ωcm and the free carrier density increased from 2.2×10¹⁶ cm⁻³ to 1.08×10¹⁸ cm⁻³ for the sample with 7 at. % of (Ga+As), which was the film with the best crystalline characteristics. The mobility was not improved substantially, but it should be considered that the heat treatment produced a material with low crystallinity, as can be concluded from the FWHM of the X-ray diffraction peaks, FIG. 21B. Notwithstanding the low crystallinity of the heat-treated films, overall, the ACC had a positive effect on the electrical properties of germanium.

### Photoconductivity

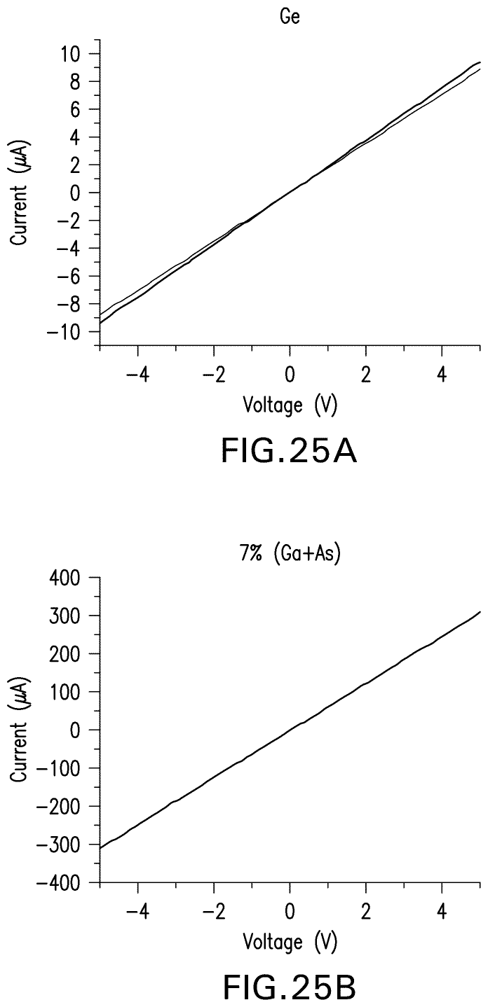

The light-induced changes in photocurrent were smaller with respect to the values in dark for the heat-treated films, both for the undoped and codoped films, FIG. 25. However, it can be noted that the ACC produced photocurrent values 45 times higher, FIG. 25B, than those of the undoped sample, FIG. 25A, for an applied voltage of 5V.

### Scope of Adjacent Compensated Codoping

The results presented here demonstrate that the Adjacent Compensated Codoping method improves the electronic properties of the host material, such as the electrical conductivity and photoelectric response measured in terms of photoconductivity, with minimal alteration of the crystalline lattice and its dynamics (phonon properties). The materials presented here where ACC was applied show that the scope of the method can vary, depending on the characteristics of the host material as well as on its position in the Periodic Table. Among these one can mention the type of chemical bond (covalent, polar covalent, ionic), degree of crystallinity, as well as the availability of adjacent codopants. For example, for group 17 elements (VIIA), the adjacent Z_{G}+1 codopants are the noble gases, which are inert. That is to say, the extent of the enhancement of electrical, photoelectric and other electronic properties will depend on the particular case of the host+ACC system. As shown in the case of cadmium telluride, the application of ACC produced benefits in the electrical and photoelectric properties far superior to those possible with simple doping or regular codoping so far reported in the literature. As it may be concluded from the applications of the ACC method presented here, optimal concentrations of adjacent compensated codopants were obtained which produced the lowest resistivity and largest photosensitivity in the host materials.

This way of choosing codopants is a unique strategy, it creates a minor change in the entropy of the host material (i.e., the structural and vibrational disorder introduced in the lattice is small because of the similarity between the elements of the host and the adjacent codopants). This type of codoping favors the solubility of impurities, produces a low level of stress in the crystalline lattice, changes in phononic properties are minor, and abrupt changes in chemical bonds due to large differences in electronegativity and other atomic properties between host and impurities are avoided. In the case of semiconductor materials, adjacent codopants favor the formation of shallow levels in the forbidden band (useful for improving the electrical conductivity), in addition to reducing the probability of creating native local charge self-compensating defects in the host material.

In general, the use of adjacent compensated codoping modifies the electronic properties of the host; in the case of semiconductor materials, ACC improves the electrical conductivity and photocurrent (photosensitivity), while the optimization of other physical properties is not ruled out.

### EXAMPLES

The following examples are presented as forms for application of the invention and are not limitative but illustrative, as they may include some variations within the spirit of the invention, which may be introduced at the discretion of persons skilled in the field of the invention.

### Example 1: CdTe Films Codoped with Silver and Iodine (Cdte:(Ag+i)) for Photovoltaic Applications

CdTe-based solar cells are the second most common photovoltaic technology in the market, the present invention provides a method for codoping CdTe in thin film solar cells. The high absorption coefficient (˜10⁴ cm⁻¹) for photon energies above their forbidden band of 1.5 eV allows CdTe layers to absorb fully the most usable portion of the solar spectrum with layers a few microns thick. The record efficiency for a laboratory CdTe solar cell is currently ˜23%. To improve this efficiency, several approaches can be pursued, including increasing the open-circuit voltage above 1 V and improving the free carrier lifetime. CdTe has been doped with Ag atoms in the past. First principle calculations suggest that Ag atoms occupying Cd sites are energetically favorable, thus acting as acceptors. Doping procedures can be effective until concentration limits by the host are reached. If this limit is exceeded, silver and silver telluride aggregates can form. In CdTe:(Ag+I) no elemental silver, nor silver telluride segregation were detected in the deposited films, demonstrating the enhanced solubility of (Ag+I) up to ˜7 at % (compared to CdTe:Ag, aggregates of Ag and Ag₂Te were present with 3 at. % of silver). The optical bandgap energy was determined by the Tauc method, obtaining values in the range of 1.4-1.5 eV. The electrical resistivity was reduced five-to-six orders of magnitude after codoping with silver and iodine.

CdTe, CdTe:Ag and CdTe:(Ag+I) films were grown by RF sputtering at different substrate temperatures. The films were characterized by XRD, UV-Vis and Raman spectroscopies, scanning electron microscopy (SEM) and Hall effect at room temperature.

### Example 2: CdS Films Codoped with Silver and Chlorine (Cds:(Ag+Cl)) for Photovoltaic Applications

Cadmium sulfide is a II-VI semiconductor material widely used in heterojunctions with CdTe, CIS (CuInSe₂) or CIGS (CuInₓGa₁₋ₓSe₂) for solar cell devices. The use of CdS in photovoltaic structures is linked not only to providing a convenient window/buffer layer, but also to the formation of a transition region, such as CdTe₁₋ₓSₓ in the case of CdTe/CdS heterojunctions, beneficial for the performance of devices. CdS films were codoped with Ag and Cl using radiofrequency sputtering on glass substrates; this was performed at different substrate temperatures. The characterization was carried out by XRD, UV-Vis-NIR and Raman spectroscopies, SEM and Hall effect at room temperature. No formation of Ag₂S was detected for concentrations of adjacent codopants up to 5 at. %. The optical band gap was determined by the Tauc method yielding values between 2.2 and 2.4 eV. The electrical resistivity dropped from 10⁶ to 250 Ω·cm after adjacent codoping.

### Example 3. GERMANIUM FILMS CODOPED WITH GALLIUM AND ARSENIC (Ge:(Ga+as)) FOR OPTOELECTRONIC APPLICATIONS

Germanium has been used in infrared sensors, optical fibers, polymer catalysts, and electronic and solar panels. Given its importance and the characteristics of being a group IV mono elemental semiconductor with covalent-type chemical bonding and indirect bandgap, its physical and electronic properties improved through adjacent codoping with gallium and arsenic (Ge:(Ga+As)).

Further, the description of the invention includes any combination or subcombination of the elements of different species and/or modalities described herein. A person skilled in the art will recognize that these features, and thus the scope of this disclosure, should be construed in light of the following claims and any equivalents thereof.

### REFERENCES

1. D. J. Chadi, K. J. Chang, Theory of the atomic and electronic structure of DX centers in GaAs and AxGa1-xAs Alloys. Phys. Rev. Lett. 61 (1988) 873.
2. D. J. Chadi, K. J. Chang, Energetics of DX center formation in GaAs and AlxGa1-xAs alloys. Phys. Rev. B 39 (1989) 10063.
3. C. H. Park, D. J. Chadi, Bulk lattice Instability in II-VI semiconductors and its effect on impurity compensation. Phys. Rev. Lett. 75 (1995) 1134.
4. C. H. Park, D. J. Chadi, Stability of deep donor and acceptor centers in GaN, AlN and BN. Phys. Rev. B 55 (1997) 12995.
5. Aron Walsh and Alex Zunger, Instilling defect tolerance in new compounds, Nature Materials 16 (2017) 964-967.
6. Alex Zunger and Oleksandr I. Malyi, Understanding doping of quantum materials. Chem. Rev., 121 (2021) 3031-3060.
7. Hiroshi Katayama-Yoshida, Kazunori Sato and Tetsuya Yamamoto, Materials design for new functional semiconductors by ab initio electronic structure calculation. JSAP International No. 6 (July 2002).
8. Hans J. Queisser and Eugene E. Haller, Defects is semiconductors: some fatal, some vital. Science 281 (1998) 945.
9. R. M. Park, M. B. Troffer, C. M. Rouleau, J. M. DePuydt, M. A. Haase, p-type ZnSe by nitrogen atom beam doping during molecular beam epitaxial growth. Appl. Phys. Lett. 57 (1990) 2127.
10. K. Ohkawa, T. karasawa, T. Mitsuyu, Characteristics of p-type ZnSe Layers grown by molecular beam epitaxy with radical doping. Jpn. J. Appl. Phys. 30 (1991) L152.
11. S. Nakamura, InGaN/AlGaN blue-light emitting diodes. J. Vac. Sci. Technol. A 13 (1995) 705.
12. Akasaki, S. Sota, H. Sakai, T. Tanaka, M. Koike, H. Amano, Electron Lett. 32 (1996) 1105.
13. Xuefen Cai, and Su-Huai Wei, Perspective on the band structure engineering and doping control of transparent conducting materials. Appl. Phys. Lett. 119 (2021) 070502.
14. W. K. Metzger, S. Grover, D. Lu, E. Colegrove, J. Moseley, C. L. Perkins, X. Li, R. Mallick, W. Zhang, R. Malik, J. Kephart, C.-S. Jiang, D. Kuciauskas, D. S. Albin, M. M. Al-Jassim, G. Xiong and M. Gloeckler, Exceeding 20% efficiency with in situ group V doping in polycrystalline CdTe solar cells. Nature Energy 4, (2019) 837-845.
15. Steven C. Erwin, Lijun Zu, Michael I. Haftel, Alexander L. Efros, Thomas A. Kennedy & David J. Norris, Doping semiconductor nanocrystals. Nature 436 (2005) 91-94.
16. Ghada H. Ahmed, Jun Yin, Osman M. Bakr, and Omar F. Mohammed, Near-unity photoluminescence quantum yield in inorganic perovskite nanocrystals by metal-ion doping. J. Chem. Phys. 152 (2020) 020902.
17. Hocheon Yoo, Keun Heo, Md. Hasan Raza Ansari and Seongjae Cho, Recent advances in electrical doping of 2D semiconductors. Nanomaterials 11, (2021) 832.
18. Jingzhao Zhang, Kinfai Tse, Manhoi Wong, Yiou Zhang, Junyi Zhu, A brief review of codoping. Front. Phys. 11 (2016) 117405.
19. H Katayama-Yoshida, T Nishimatsu, T Yamamoto, and N Orita, Codoping method for the fabrication of low-resistivity wide band-gap semiconductors in p-type GaN, p-type AlN and n-type diamond: prediction versus experiment. J. Phys.: Condens. Matter 13 (2001) 8901-8914.
20. Tetsuya Yamamoto and Hiroshi Katayama-Yoshida, Solution using a codoping method to unipolarity for the fabrication of p-type ZnO. Jpn. J. Appl. Phys. 38 (1999) L 166-L 169.
21. Yanqin Gai, Jingbo Li, Shu-Shen Li, Jian-Bai Xia, and Su-Huai Wei. Design of narrow-gap TiO₂: a passivated codoping approach for enhanced photoelectrochemical activity. Phys. Rev. Letters 102 (2009) 036402.
22. Alfredo Beristain-Bautista, Daniel Olguín, and Sergio Jiménez-Sandoval, nto p-type conductivity transition and band-gap renormalization in ZnO:(Cu+Te) codoped films. Phys. Rev. Materials 5 (2021) 065402.
23. Baoying Dou, Qingde Sun, and Su-Huai Wei, Effects of codoping in semiconductors: CdTe. Phys. Rev. B 104 (2021) 245202.

24 Peter Yu and Manuel Cardona, Fundamentals of Semiconductors, Physics and Materials Properties 4 th Ed, Springer-Verlag Berlin Heidelberg, p. 170 (2010).
25. Alex Zunger and Oleksandr I. Malyi. Understanding doping of quantum materials. Chem. Rev. 121 (2021) 3031-3060.
26. A. Romeo, and E. Artegiani, CdTe-Based thin film solar cells: past, present and future. Energies 14 (2021) 1684.
27. M. Zghaibeh., P. C. Okonkwo, W. Emori, T. Ahmed, A. M. A. Mohamed, M. Allyu and G. J. Ogunleye, CdTe solar cells fabrication and examination techniques: a focused review. Int. J. Green Energy 20 (2023) 555-570.
28. Manh Cuong Nguyen, Jin-Ho Choi, Xin Zhao, Cai-Zhuang Wang, Zhenyu Zhang, and Kai-Ming Ho, New layered structures of cuprous chalcogenides as thin film solar cell materials: Cu₂Te and Cu₂Se. Phys. Rev. Lett. 111 (2013) 1-5.
29. S. H. Wei and S. B. Zhang, Chemical trends of defect formation and doping limit in II-VI semiconductors: The case of CdTe. Phys. Rev. B 66 (2002) 1-10.
30. Elisa Artegiani, Jonathan D. Major, Huw Shiel, Vin Dhanak, Claudio Ferrari and Alessandro Romeo. How the amount of copper influences the formation and stability of defects in CdTe solar cells. Sol. Energy Mater. Sol. Cells 204 (2020) 110228.
31. Anithambigai, P., Shanmugan, S., Mutharasu, D. & Ibrahim, K. Studies on structural properties of CdTe (doped Ag) thin films on glass substrates-solar cell applications. AIP Conf. Proc. 1250, (2010) 341-344.
32. D. Nam, H. Cheong, A. S. Opanasyuk, P. V. Koval, V. V. Kosyak, and P. M. Fochuk, Raman investigation on thin and thick CdTe films obtained by close spaced vacuum sublimation technique. Phys. Status Solidi Curr. Top. Solid State Phys. 11 (2014) 1515-1518.
33. H. L. Porter, A. L. Cai, and J. F. Muth, J. Narayan, Enhanced photoconductivity of ZnO films Co-doped with nitrogen and tellurium. Appl. Phys. Lett. 86 (2005) 211918.
34. J. S. Jie, W. J. Zhang, Y. Jiang, X. M. Meng, Y. Q. Li, and S. T. Lee. Li, and S. T. Lee. Photoconductive characteristics of single-srystal CdS nanoribbons, Nano Lett. 2006, 6, 9, 1887-1892.
35. H. Shimada, T. Masumi, Dynamics of hot Electrons “Accumulated” in the velocity space of CdS with acoustic phonon interactions. J. Phys. Soc. Jpn. 62 (1993) 3203.
36. R. Radhakrishnan Sumathi, Nikolay Abrosimov, Kevin-P. Gradwohl, Matthias Czupalla, Jörg Fischer. Growth of heavily doped Germanium single crystals for mid-Infrared Applications. J. Cryst. Growth 535 (2020) 125490.
37. Madhav Patel, Athanasios K. Karamalidis, Germanium: A review of its US demand, uses, resources, chemistry, and separation technologies. Separation and Purification Technology 275 (2021) 118981.
38. J. H. Parker, Jr, D. W. Feldman, and M. Ashkin, Raman scattering by silicon and germanium. Phys. Rev 155 (1967) 712.
39. L. Q. Huston, B. C. Johnson, B. Haberl, S. Wong, J. S. Williams, and J. E. Bradby, Thermal stability of simple tetragonal and hexagonal diamond germanium, J. Appl. Phys. 122, (2017) 175108.

1. A process for impurification of semiconductor materials, comprising adjacent compensated codoping according to the following steps:
a. providing a mono or multicomponent (one element, binary, ternary, quaternary, etc.) host material of a semiconductor compound with generic chemical formula AEGJ . . . , where AEGJ . . . represent chemical elements forming the compound; select any two chemical elements forming the compound A and G (one cation and one anion, both cations, or both anions) which have atomic numbers Z_{A} and Z_{G}; the host may as well be formed by a single element A;
b. select two impurities Q and X from the Periodic Table of the chemical elements comprising the codopants under the following scheme:
i. considering the selected chemical elements of the host A and G, impurity Q is the chemical element with atomic number Z_{A}−1 and impurity X is the chemical element with atomic number Z_{G}+1; or impurity Q is the chemical element with atomic number Z_{A}+1 and impurity X is the chemical element with atomic number Z_{G}−1; or
ii. considering the selected chemical elements of the host A and G, impurity Q is the chemical element with atomic number Z_{A}−2 and impurity X is the chemical element with atomic number Z_{G}+2; or impurity Q is the chemical element with atomic number Z_{A}+2 and impurity X is the chemical element with atomic number Z_{G}−2; or
iii. considering the selected chemical elements of the host A and G, impurity Q is the chemical element with atomic number Z_{A}−1 and impurity X is the chemical element with atomic number Z_{G}+2; or impurity Q is the chemical element with atomic number Z_{A}+2 and impurity X is the chemical element with atomic number Z_{G}−1;
c. performing the host adjacent codoping process with the selected impurities.

2. The adjacent compensated codoping process of claim 1, wherein the host material is formed by a single element A, and impurity Q and impurity X correspond to the chemical elements with atomic numbers Z_{A}−1 and Z_{A}+1; or with atomic numbers Z_{A}−2 and Z_{A}+2; or combinations of atomic numbers Z_{A}−1 and Z_{A}+2; or Z_{A}−2 and Z_{A}+1.

3. The adjacent compensated codoping process of claim 1, wherein the growth technique is selected from the group comprising:
codoping during crystal growth,
codoping by growing by Czochralski's method,
codoping by vapor phase epitaxial methods,
codoping by electrodeposition,
codoping by pulsed laser deposition,
codoping by atomic layer deposition,
codoping by chemical spraying, diffusion and ion implantation,
codoping by close space vapor transport,
codoping by sputtering (DC or RF),
codoping by spray pyrolysis,
codoping by any combination or modification of these techniques, and
codoping by any other method to grow materials in bulk or to deposit thin or thick films.

4. A CdTe semiconductor material as a host material codoped with Silver and Iodine, obtained according to the process of claim 1.

5. A CdS semiconductor material as a host material, codoped with Silver and Chlorine, obtained according to the process of claim 1.

6. A Ge semiconductor material as a host material, codoped with Gallium and Arsenic, obtained according to the process of claim 1.

7. A process for obtaining CdTe semiconductor films as host material codoped with Silver and Iodine by adjacent compensated codoping, through radio frequency sputtering comprising:
a. conducting the formation of the sputtering target using a powdered mixture of the compounds CdTe and AgI by pressing it inside a stainless-steel die at room temperature until a compact target of 5.08 cm (2 inch) in diameter and 3.175 mm (⅛ inch) thick is formed;
b. applying a temperature of 275° C. to the glass substrate during the growth of the films;
c. using argon as working gas at a pressure of 1 mTorr, a radio frequency power of 35 W applied to the target during 30 minutes, with the target-substrate distance of 8.5 cm; and
d. applying a rotation to the substrate holder of 50 rpm during growth.

8. A process for obtaining a CdS semiconductor film as a host material, codoped with Silver and Chlorine by adjacent compensated codoping, through radio frequency sputtering comprising:
a. conducting the formation of the sputtering target using a powdered mixture of the compounds CdS and AgCl by pressing it inside a stainless-steel die at room temperature until a compact target of 5.08 cm (2″) in diameter and 3.175 mm (⅛″) thick is formed:
b. applying a temperature of 250° C. to the glass substrate during the growth of the films;
c. using argon as working gas at a pressure of 1 mTorr, a radio frequency power of 35 W applied to the target for 20 minutes, with the target-substrate distance of 8.5 cm; and
d. applying a rotation to the substrate holder of 50 rpm during growth.

9. A process for obtaining Ge semiconductor material as a host material, codoped with Gallium and Arsenic by adjacent compensated codoping, through radio frequency sputtering comprising:
a. conducting the formation of the sputtering target using a powdered mixture of Ge and GaAs by pressing it inside a stainless-steel die at room temperature until a compact target of 5.08 cm (2 inch) in diameter and 3.175 mm (⅛ inch) thick is formed:
b. applying a temperature of 300° C. to the glass substrate during the growth of the films;
c. using argon as working gas at a pressure of 1 mTorr, a radio frequency power of 35 W applied to the target for 30 minutes, with the target-substrate distance of 8.5 cm; and
d. applying a rotation to the substrate holder of 50 rpm during growth,
e. thermal annealing after growth for 30 minutes at 550° C.
